(19) United States
(12) Patent Application Publication
(10) Pub. No.: US 2019/0346769 A1
(43) Pub. Date: Nov. 14, 2019

(54) PATTERN INSPECTION APPARATUS AND PATTERN INSPECTION METHOD

(71) Applicant: NuFlare Technology, Inc., Yokohama-shi (JP)

(72) Inventors: Hideaki Hashimoto, Yokohama-shi (JP); Riki Ogawa, Kawasaki-shi (JP); Masataka Shiratsuchi, Kawasaki-shi (JP); Ryoichi Hirano, Setagaya-ku (JP)

(73) Assignee: NuFlare Technology, Inc., Yokohama-shi (JP)

(21) Appl. No.: 16/400,182

(22) Filed: May 1, 2019

(30) Foreign Application Priority Data
May 14, 2018 (JP) 2018-092777

(51) Int. Cl. G03F 7/20; G01N 21/956; G06T 7/00; H01L 21/66; G01B 11/24

(52) U.S. Cl. CPC G03F 7/7065; G01N 21/95607; G01N 2021/95676; H01L 22/12; G01B 11/24; G06T 7/0004

(57) ABSTRACT

According to one aspect of the present invention, a pattern inspection apparatus includes an inspected image acquisition mechanism configured to acquire an inspected image of a figure pattern formed on an inspection target object, using an electron beam; a reference image generation processing circuit configured to generate a reference image corresponding to the inspected image; a contour data generation processing circuit configured to generate contour data defining a contour line of the figure pattern; a comparison processing circuit configured to compare the inspected image and the reference image and determine whether there is a defect based on a result of a comparison; and a defect selection processing circuit configured to select a defect within a range preset based on the contour line as a valid defect, from at least one defect determined to be a defect by the comparison, using the contour data.

### CROSS-REFERENCE TO RELATED APPLICATION

This application is based upon and claims the benefit of priority from prior Japanese Patent Application No. 2018-092777 filed on May 14, 2018 in Japan, the entire contents of which are incorporated herein by reference.

### BACKGROUND OF THE INVENTION

### Field of the Invention

Embodiments described herein relate generally to a pattern inspection apparatus and a pattern inspection method. For example, the embodiments described herein relate generally to a method for inspecting an image for inspection acquired by using an electron beam.

### Related Art

Recently, with an increase in the degree of integration and an increase in the capacity of a large-scale integrated circuit (LSI), a circuit line width required for a semiconductor element decreases. Further, improvement of a yield is indispensable for manufacturing the LSI requiring a large manufacturing cost. However, as represented by a 1-Gbit random access memory (DRAM), patterns configuring the LSI are on the order of submicron to nanometer. In recent years, with the miniaturization of a dimension of an LSI pattern formed on a semiconductor wafer, a dimension to be detected as a pattern defect is also extremely small. Therefore, it is necessary to improve accuracy of a pattern inspection apparatus for inspecting a defect of an ultrafine pattern transferred to the semiconductor wafer. As one of major factors decreasing the yield, there is a pattern defect of a mask used at the time of exposing and transferring an ultrafine pattern on the semiconductor wafer by photolithography technology. For this reason, it is necessary to improve the accuracy of the pattern inspection apparatus for inspecting a defect of a transfer mask used for manufacturing the LSI.

As an inspection method, a method of performing inspection by comparing a measurement image obtained by imaging a pattern formed on a substrate, such as a semiconductor wafer or a lithography mask, with design data or a measurement image obtained by imaging the same pattern on the substrate is known. For example, as a pattern inspection method, there are a “die to die inspection” for comparing measurement image data obtained by imaging the same patterns at different places on the same substrate with each other and a “die to database inspection” for generating design image data (reference image) on the basis of pattern-designed design data and comparing the design image data with a measurement image to be measurement data obtained by imaging a pattern. The imaged image is sent as the measurement data to a comparison circuit. In the comparison circuit, after positions of the images are adjusted, the measurement data and the reference data are compared according to an appropriate algorithm. When the measurement data and the reference data are not matched, it is determined that there is a pattern defect.

In the pattern inspection apparatus, in addition to development of an apparatus that irradiates an inspection target substrate with a laser beam and images a transmitted image or a reflected image, development of an inspection apparatus that scans the inspection target substrate with an electron beam, detects secondary electrons emitted from the inspection target substrate according to irradiation of the electron beam, and acquires a pattern image is also advanced. In the inspection apparatus using the electron beam, development of an apparatus using multiple beams is also advanced. Since the number of secondary electrons in the case of acquiring an image using an electron beam is smaller than the number of photons in the case of acquiring an image by using a laser beam such as ultraviolet rays, an amount of information is small, and in image data obtained by using the electron beam, a ratio of noise relatively increases and an influence of the noise is greatly received. For this reason, so-called pseudo defects that are unnecessary for detection may occur frequently. For example, in a scanning electron microscope (SEM) or the like, filter processing such as a Gaussian filter is used for noise reduction (for example, refer to JP 2829968 B2). However, in an average filter, a Gaussian filter, or a median filter to be conventionally used, it is difficult to avoid an influence of large noise generated randomly such as shot noise. In addition, from the viewpoint of improving the throughput of the inspection apparatus, it is also difficult to perform complicated digital filter processing requiring a large number of calculations.

### BRIEF SUMMARY OF THE INVENTION

According to one aspect of the present invention, a pattern inspection apparatus includes:
an inspected image acquisition mechanism configured to acquire an inspected image of a figure pattern formed on an inspection target object, using an electron beam;
a reference image generation processing circuit configured to generate a reference image corresponding to the inspected image;
a contour data generation processing circuit configured to generate contour data defining a contour line of the figure pattern;
a comparison processing circuit configured to compare the inspected image and the reference image and determine whether there is a defect based on a result of a comparison; and
a defect selection processing circuit configured to select a defect within a range preset based on the contour line as a valid defect, from at least one defect determined to be a defect by the comparison, using the contour data.

According to another aspect of the present invention, a pattern inspection apparatus includes:
an inspected image acquisition mechanism configured to acquire an inspected image of a figure pattern formed on an inspection target object, using an electron beam;
a reference image generation processing circuit configured to generate a reference image corresponding to the inspected image;
a contour data generation processing circuit configured to generate contour data defining a contour line of the figure pattern;
an image processing circuit configured to process the inspected image and the reference image using the contour data; and
a comparison processing circuit configured to compare the inspected image processed and the reference image processed.

According to yet another aspect of the present invention, a pattern inspection method includes:
acquiring an inspected image of a figure pattern formed on an inspection target object, using an electron beam;
generating a reference image corresponding to the inspected image;
generating contour data defining a contour line of the figure pattern;
comparing the inspected image and the reference image and determining whether there is a defect based on a result of a comparison; and
selecting a defect within a range preset based on the contour line as a valid defect, from at least one defect determined to be a defect by the comparison, using the contour data, and outputting the defect.

According to yet another aspect of the present invention, a pattern inspection apparatus includes:
an inspected image acquisition mechanism configured to acquire an inspected image of a figure pattern formed on an inspection target object, using an electron beam;
a contour data generation processing circuit configured to generate contour data defining a contour line of the figure pattern;
a comparison processing circuit configured to compare first and second inspected images provided with the same pattern and determine whether there is a defect based on a result of a comparison; and
a defect selection processing circuit configured to select a defect within a range preset based on the contour line as a valid defect, from at least one defect determined to be a defect by the comparison, using the contour data.

According to yet another aspect of the present invention, a pattern inspection apparatus includes:
an inspected image acquisition mechanism configured to acquire an inspected image of a figure pattern formed on an inspection target object, using an electron beam;
a contour data generation processing circuit configured to generate contour data defining a contour line of the figure pattern;
an image processing circuit configured to process first and second inspected images provided with the same pattern using the contour data; and
a comparison processing circuit configured to compare the first and second inspected images processed.

### BRIEF DESCRIPTION OF THE DRAWINGS

FIG. 1 is a configuration diagram showing a configuration of a pattern inspection apparatus in a first embodiment;

FIG. 2 is a conceptual diagram showing a configuration of a shaping aperture array substrate in the first embodiment;

FIG. 3 is a diagram showing an example of a plurality of chip regions formed on a semiconductor substrate in the first embodiment;

FIG. 4 is a diagram showing an example of an irradiation region of multiple beams and a measurement pixel in the first embodiment;

FIGS. 5A and 5B are diagrams showing an example of an acquisition image in the first embodiment;

FIGS. 6A and 6B are diagrams showing an example of an enlarged view of an acquisition image in the first embodiment;

FIG. 7 is a flowchart showing main steps of an inspection method in the first embodiment;

FIG. 8 is a configuration diagram showing an example of an internal configuration of a comparison circuit in the first embodiment;

FIG. 9 is a configuration diagram showing an example of an internal configuration of a defect selection circuit in the first embodiment;

FIG. 10 is a diagram showing an example of a defect selection region in the first embodiment;

FIG. 11 is a flowchart showing internal steps of a defect selection step in the first embodiment;

FIG. 12 is a diagram showing an example of a defect and a surrounding contour line in the first embodiment;

FIG. 13 is a diagram showing an example of a detection intensity distribution of an inspected image in the first embodiment;

FIG. 14 is a flowchart showing main steps of a modification of the inspection method in the first embodiment;

FIG. 15 is a configuration diagram showing a configuration of a pattern inspection apparatus in a second embodiment;

FIG. 16 is a flowchart showing main steps of an inspection method in the second embodiment;

FIG. 17 is a diagram showing an example of a valid inspection region in the second embodiment;

FIG. 18 is a configuration diagram showing an example of an internal configuration of an image processing circuit in the second embodiment;

FIG. 19 is a flowchart showing main steps of a modification of the inspection method in the second embodiment;

FIG. 20 is a diagram showing a relation between a distance from a contour line and weighting of a defect in a comparative example (second embodiment) of a third embodiment;

FIG. 21 is a diagram showing an example of a relation between a distance from a contour line and weighting of a defect in the third embodiment;

FIG. 22 is a diagram showing another example of a relation between a distance from a contour line and weighting of a defect in the third embodiment;

FIG. 23 is a diagram showing another example of a relation between a distance from a contour line and weighting of a defect in the third embodiment;

FIG. 24 is a diagram showing another example of a relation between a distance from a contour line and weighting of a defect in the third embodiment;

FIGS. 25A and 25B are diagrams showing an example of an inspected image in the third embodiment;

FIGS. 26A and 26B are diagrams showing an example of a filter function in a first comparative example of a fourth embodiment;

FIG. 27 is a diagram showing an example of a contour line distance combination filter function in the fourth embodiment;

FIGS. 28A to 28C are diagrams showing an example of an inspected image filtered by a Gaussian filter in the first comparative example of the fourth embodiment;

FIGS. 29A to 29D are diagrams showing an example of an inspected image filtered by a brightness difference filter in a second comparative example of the fourth embodiment;

FIGS. 30A to 30D are diagrams showing an example of an inspected image filtered by a contour line distance independent filter in a third comparative example of the fourth embodiment;

FIGS. 31A to 31G are diagrams showing an example of an inspected image filtered by a bilateral filter in a fourth comparative example of the fourth embodiment;

FIGS. 32A to 32H are diagrams showing an example of an inspected image filtered by a contour line distance combination filter in the fourth embodiment; and

FIGS. 33A to 33C are diagrams showing an example of a contour line distance filter kernel in a modification of the fourth embodiment.

### DETAILED DESCRIPTION OF THE INVENTION

In the following embodiments, an apparatus and a method capable of reducing occurrence of pseudo defects that are unnecessary for detection even where large noise such as shot noise occurs when a defect inspection is performed using an image acquired by using an electron beam will be described.

### First Embodiment

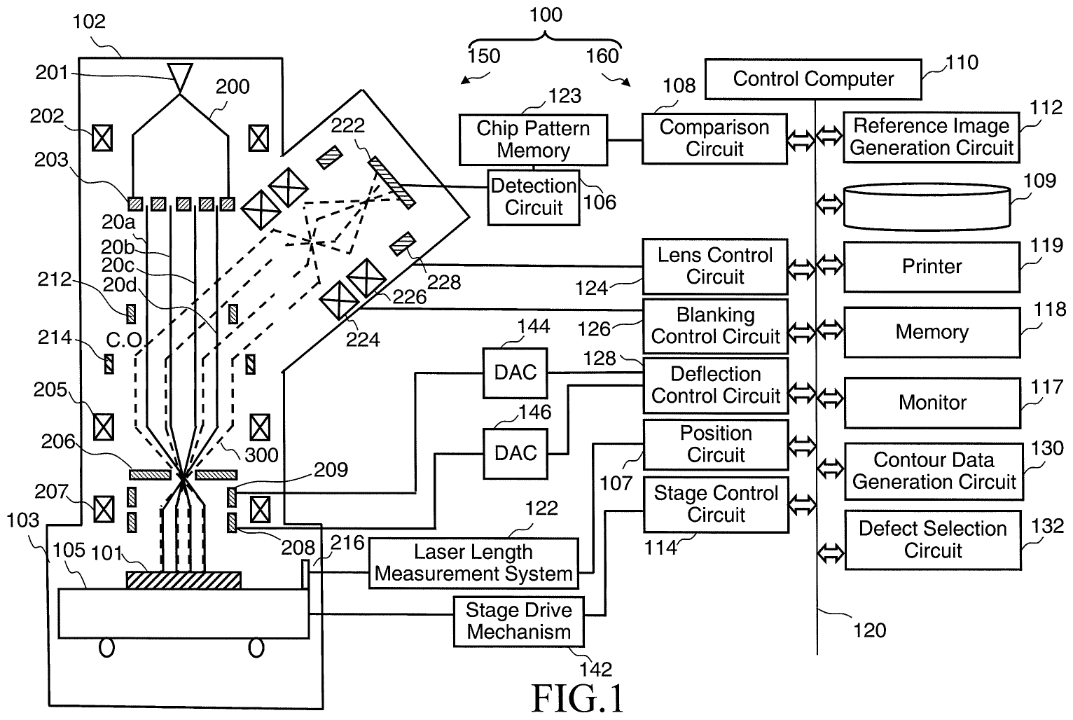

FIG. 1 is a configuration diagram showing a configuration of a pattern inspection apparatus in a first embodiment. In FIG. 1, an inspection apparatus 100 to inspect a pattern formed on a substrate is an example of an electron beam inspection apparatus. Further, the inspection apparatus 100 is an example of a multiple beam inspection apparatus. Further, the inspection apparatus 100 is an example of an electron beam image acquisition apparatus. Further, the inspection apparatus 100 is an example of a multiple beam image acquisition apparatus. The inspection apparatus 100 includes an image acquisition mechanism 150 and a control system circuit 160. The image acquisition mechanism 150 includes an electron beam column 102 (also referred to as an electron optical column) (an example of a multiple beam column), an inspection chamber 103, a detection circuit 106, a chip pattern memory 123, a stage drive mechanism 142, a laser length measurement system 122. In the electron beam column 102, an electron gun assembly 201, an illumination lens 202, a shaping aperture array substrate 203, a reduction lens 205, a limitation aperture substrate 206, an objective lens 207, a main deflector 208, a sub-deflector 209, a collective blanking deflector 212, a beam separator 214, projection lenses 224 and 226, a deflector 228, and a multi-detector 222 are disposed.

In the inspection chamber 103, an XY stage 105 to be movable on at least an XY plane is disposed. On the XY stage 105, a substrate 101 (target object) to be inspected is disposed. The substrate 101 includes a mask substrate for exposure and a semiconductor substrate such as a silicon wafer. When the substrate 101 is the semiconductor substrate, a plurality of chip patterns (wafer dies) are formed on the semiconductor substrate. When the substrate 101 is the mask substrate for exposure, a chip pattern is formed on the mask substrate for exposure. The chip pattern is configured by a plurality of figure patterns. A plurality of chip patterns (wafer dies) are formed on the semiconductor substrate by exposing and transferring the chip pattern formed on the mask substrate for exposure to the semiconductor substrate a plurality of times. Hereinafter, the case where the substrate 101 is the semiconductor substrate will be mainly described. The substrate 101 is disposed on the XY stage 105 with a pattern formation surface oriented upward, for example. Further, a mirror 216 for reflecting a laser beam for laser length measurement emitted from the laser length measurement system 122 disposed outside the inspection chamber 103 is disposed on the XY stage 105. The multi-detector 222 is connected to the detection circuit 106 outside the electron beam column 102. The detection circuit 106 is connected to the chip pattern memory 123.

In the control system circuit 160, a control computer 110 for controlling the entire inspection apparatus 100 is connected to a position circuit 107, a comparison circuit 108, a reference image generation circuit 112, a stage control circuit 114, a lens control circuit 124, a blanking control circuit 126, a deflection control circuit 128, a contour data generation circuit 130, a defect selection circuit 132, a storage device 109 such as a magnetic disk drive, a monitor 117, a memory 118, and a printer 119 via a bus 120. Further, the deflection control circuit 128 is connected to a digital-analog conversion (DAC) amplifiers 144 and 146. The DAC amplifier 144 is connected to the main deflector 208 and the DAC amplifier 146 is connected to the sub-deflector 209.

Further, the chip pattern memory 123 is connected to the comparison circuit 108. Further, the XY stage 105 is driven by the stage drive mechanism 142 under the control of the stage control circuit 114. In the stage drive mechanism 142, for example, a drive system such as three-axis (X-Y-θ) motors driven in an X direction, a Y direction, and a θ direction in a stage coordinate system is configured and the XY stage 105 is movable. For these X-axis motor, Y-axis motor, and θ-axis motor not shown in the drawings, for example, step motors can be used. The XY stage 105 is movable in a horizontal direction and a rotational direction by the motors of the X, Y, and θ axes. In addition, a movement position of the XY stage 105 is measured by the laser length measurement system 122 and is supplied to the position circuit 107. The laser length measurement system 122 receives reflected light from the mirror 216 and measures a position of the XY stage 105 by the principle of a laser interference method. In the stage coordinate system, for example, an X direction, a Y direction, and a θ direction are set with respect to a plane orthogonal to an optical axis of multiple primary electron beams.

A high-voltage power supply circuit not shown in the drawings is connected to the electron gun assembly 201 and an electron group emitted from a cathode is accelerated by application of an acceleration voltage from the high-voltage power supply circuit between a filament and an extraction electrode not shown in the drawings in the electron gun assembly 201, application of a voltage of a predetermined extraction electrode (Wehnelt), and heating of a cathode at a predetermined temperature and becomes an electron beam 200. As the illumination lens 202, the reduction lens 205, the objective lens 207, and the projection lenses 224 and 226, for example, electromagnetic lenses are used. These lenses are controlled by the lens control circuit 124. The beam separator 214 is also controlled by the lens control circuit 124. Each of the collective blanking deflector 212 and the deflector 228 is configured by an electrode group of at least two poles and is controlled by the blanking control circuit 126. The main deflector 208 is configured by an electrode group of at least four poles and is controlled by the deflection control circuit 128 via the DAC amplifier 144 disposed for each electrode. Similarly, the sub-deflector 209 is configured by an electrode group of at least four poles and is controlled by the deflection control circuit 128 via the DAC amplifier 146 disposed for each electrode.

Here, in FIG. 1, the configuration necessary for describing the first embodiment is described. The inspection apparatus 100 may generally include other necessary configuration.

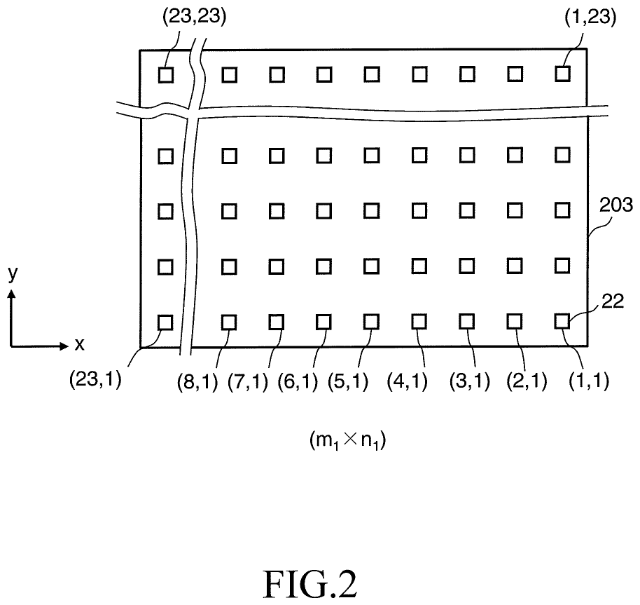

FIG. 2 is a conceptual diagram showing a configuration of a shaping aperture array substrate in the first embodiment. In FIG. 2, in the shaping aperture array substrate 203, m₁×n₁ (m₁ and n₁ are integers of 2 or more) holes (openings) 22 to be arranged two-dimensionally in a width direction (x direction) and a length direction (y direction) are formed in the x and y directions at a predetermined arrangement pitch. In an example of FIG. 2, the case where 23×23 holes (openings) 22 are formed is shown. Each hole 22 is formed of a rectangle having the same size and shape. Alternatively, each hole 22 may be circular with the same outer diameter. A part of the electron beam 200 passes through the plurality of holes 22, so that the multiple beams 20 are formed. Here, an example in which two rows or more of holes 22 are disposed in both the width and length directions (x and y directions) is shown. However, the present disclosure is not limited thereto. For example, a plurality of rows of holes 22 may be disposed in one of the width and length (x and y directions) and only one row of holes 22 may be disposed in the other direction. In addition, a method of disposing the holes 22 is not limited to the case where the holes 22 are disposed in a lattice in the width and length directions, as shown in FIG. 2. For example, the holes in a k-th row in the length direction (y direction) and the holes in a (k+1)-th row may be disposed to be deviated by a dimension a in the width direction (x direction). Likewise, the holes in the (k+1)-th row in the length direction (y direction) and the holes in a (k+2)-th row may be disposed to be deviated by a dimension b in the width direction (x direction).

The image acquisition mechanism 150 acquires an inspected image of a figure pattern from the substrate 101 on which the figure pattern has been formed by using the multiple beams 20 based on the electron beam. Hereinafter, an operation of the image acquisition mechanism 150 in the inspection apparatus 100 will be described.

The electron beam 200 emitted from the electron gun assembly 201 (emission source) illuminates the entire shaping aperture array substrate 203 substantially vertically by the illumination lens 202. As shown in FIG. 2, the plurality of rectangular holes 22 (openings) are formed in the shaping aperture array substrate 203 and the electron beam 200 illuminates a region including all of the plurality of holes 22. Each part of the electron beam 200 emitted to the positions of the plurality of holes 22 passes through the plurality of holes 22 of the shaping aperture array substrate 203, so that a plurality of rectangular electron beams (multiple beams) 20a to 20d (shown by solid lines in FIG. 1) (multiple primary electron beams) are formed.

The formed multiple beams 20a to 20d form a crossover (C.O.) and passes through the beam separator 214 disposed at a crossover position of each beam of the multiple beams 20. Then, the multiple beams 20a to 20d are reduced by the reduction lens 205 and travels toward a center hole formed in the limitation aperture substrate 206. Here, when the entire multiple beams 20a to 20d are collectively deflected by the collective blanking deflector 212 disposed between the shaping aperture array substrate 203 and the reduction lens 205, positions of the multiple beams 20a to 20d deviate from the center hole of the limitation aperture substrate 206 and the multiple beams 20a to 20d are shielded by the limitation aperture substrate 206. On the other hand, the multiple beams 20a to 20d that are not deflected by the collective blanking deflector 212 pass through the center hole of the limitation aperture substrate 206 as shown in FIG. 1. Blanking control is performed by turning on/off the collective blanking deflector 212 and turning on/off of the beam is collectively controlled. As described above, the limitation aperture substrate 206 shields the multiple beams 20a to 20d deflected so that the beams are turned off by the collective blanking deflector 212. The multiple beams 20a to 20d for inspection are formed by a group of beams formed until the beams are turned off after the beams are turned on and have passed through the limitation aperture substrate 206. The multiple beams 20a to 20d that have passed through the limitation aperture substrate 206 are focused on a surface of the substrate 101 (target object) by the objective lens 207 and become a pattern image (beam diameter) of a desired reduction ratio. By the main deflector 208 and the sub-deflector 209, the entire multiple beams 20 having passed through the limitation aperture substrate 206 are collectively deflected in the same direction and are emitted to each irradiation position of each beam on the substrate 101. In this case, the main deflector 208 collectively deflects the entire multiple beams 20 to a reference position of the mask die scanned by the multiple beams 20. In the first embodiment, for example, scanning is performed while the XY stage 105 is continuously moved. Therefore, the main deflector 208 further performs tracking deflection to follow the movement of the XY stage 105. In addition, the sub-deflector 209 collectively deflects the entire multiple beams 20 so that each beam scans a corresponding region. The multiple beams 20 emitted at one time are ideally arranged at a pitch obtained by multiplying the arrangement pitch of the plurality of holes 22 of the shaping aperture array substrate 203 by the desired reduction ratio (1/a) described above. As such, the electron beam column 102 irradiates the substrate 101 with m₁×n₁ multiple beams 20 two-dimensionally at one time. A secondary electron flux (multiple secondary electron beams 300) (dotted lines of FIG. 1) including reflected electrons corresponding to the respective beams of the multiple beams 20 are emitted from the substrate 101 due to irradiation of a desired position of the substrate 101 with the multiple beams 20.

The multiple secondary electron beams 300 emitted from the substrate 101 are refracted to the center side of the multiple secondary electron beams 300 by the objective lens 207 and travel toward the center hole formed in the limitation aperture substrate 206. The multiple secondary electron beams 300 that have passed through the limitation aperture substrate 206 are refracted substantially parallel to an optical axis by the reduction lens 205 and travel to the beam separator 214.

Here, the beam separator 214 generates an electric field and a magnetic field in directions orthogonal to each other on a plane orthogonal to a traveling direction (optical axis) of the multiple beams 20. The electric field exerts a force in the same direction regardless of the traveling direction of electrons. Meanwhile, the magnetic field exerts a force according to the Fleming's left-hand rule. Therefore, it is possible to change the direction of the force acting on the electrons depending on a penetration direction of the electrons. The force due to the electric field and the force due to the magnetic field cancel each other in the multiple beams 20 (primary electron beams) penetrating the beam separator 214 from the upper side and the multiple beams 20 go straight downward. On the other hand, in the multiple secondary electron beams 300 penetrating the beam separator 214 from the lower side, both the force due to the electric field and the force due to the magnetic field act in the same direction and the multiple secondary electron beams 300 are bent obliquely upward.

The multiple secondary electron beams 300 bent obliquely upward are projected onto the multi-detector 222 while being refracted by the projection lenses 224 and 226. The multi-detector 222 detects the projected multiple secondary electron beams 300. The multi-detector 222 has, for example, a diode type two-dimensional sensor not shown in the drawings. At a position of the diode type two-dimensional sensor corresponding to each beam of the multiple beams 20, each secondary electron of the multiple secondary electron beams 300 collides with the diode type two-dimensional sensor, generates electrons, and generates secondary electron image data for each pixel to be described later. Further, since scanning is performed while the XY stage 105 is continuously moved, the tracking deflection is performed as described above. The deflector 228 deflects the multiple secondary electron beams 300 to irradiate a desired position on a light reception surface of the multi-detector 222 in accordance with the movement of the deflection position associated with the tracking deflection.

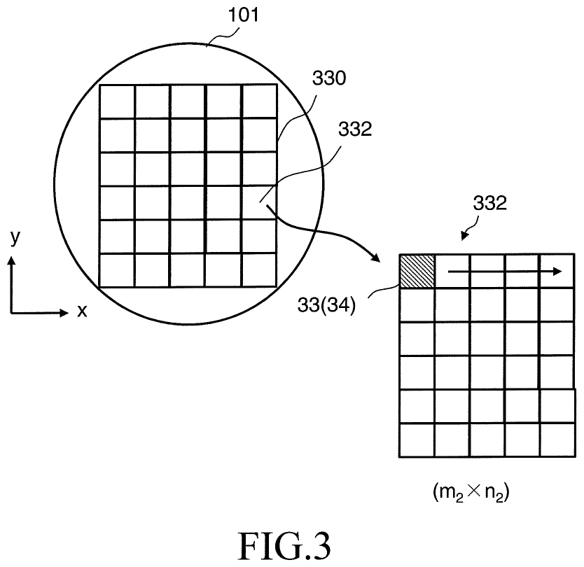

FIG. 3 is a diagram showing an example of a plurality of chip regions formed on a semiconductor substrate in the first embodiment. In FIG. 3, when the substrate 101 is a semiconductor substrate (wafer), a plurality of chips (wafer dies) 332 are formed in a two-dimensional array in an inspection region 330 of the semiconductor substrate (wafer). In each chip 332, a mask pattern for one chip formed on the mask substrate for exposure is reduced to 1/4 by an exposure device (stepper) not shown in the drawings and is transferred. An inner portion of each chip 332 is divided into m₂×n₂ (m₂ and n₂ are integers of 2 or more) mask dies 33 to be arranged two-dimensionally in a width direction (x direction) and a length direction (y direction). In the first embodiment, the mask die 33 becomes a unit inspection region.

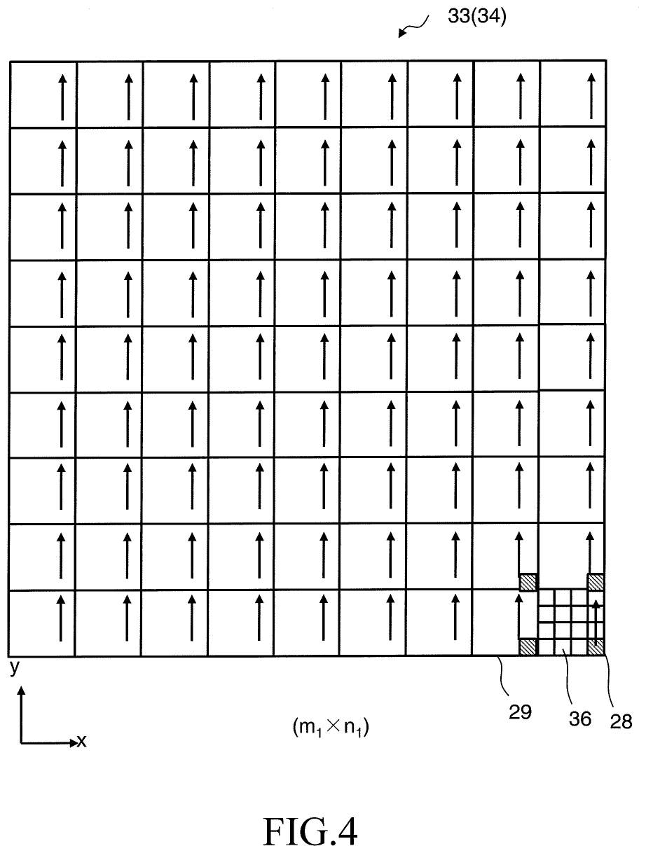

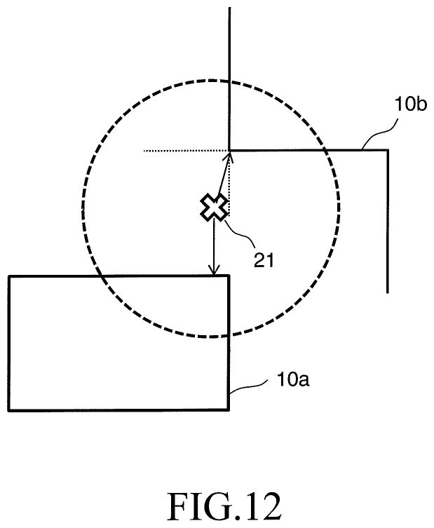

FIG. 4 is a diagram showing an example of an irradiation region of multiple beams and a measurement pixel in the first embodiment. In FIG. 4, each mask die 33 is divided into a plurality of mesh-like mesh regions with a beam size per beam of the multiple beams 20, for example. Each of the mesh regions becomes the measurement pixel 36 (unit irradiation region). In the example of FIG. 4, the case of multiple beams of 8×8 rows is shown. An irradiation region 34 that can be irradiated with the beams with one irradiation of the multiple beams 20 is defined by (an x-direction size obtained by multiplying an inter-beam pitch in the x direction of the multiple beams 20 on the surface of the substrate 101 by the number of beams in the x direction)×(a y-direction size obtained by multiplying an inter-beam pitch in the y direction of the multiple beams 20 on the surface of the substrate 101 by the number of beams in the y direction). In the example of FIG. 12, the case where the irradiation region 34 has the same size as the mask die 33 is shown. However, the present disclosure is not limited thereto. The irradiation region 34 may be smaller than the mask die 33. Alternatively, the irradiation region 34 may be larger than the mask die 33. A plurality of measurement pixels 28 (irradiation positions of the beams at one shot) that can be irradiated with the beams by one irradiation of the multiple beams 20 are shown in the irradiation region 34. In other words, a pitch between adjacent measurement pixels 28 becomes a pitch between the respective beams of the multiple beams. In the example of FIG. 4, one sub-irradiation region 29 is configured by a square region surrounded by four adjacent measurement pixels 28 and including one measurement pixel 28 among the four measurement pixels 28. In the example of FIG. 4, the case where each of the sub-irradiation regions 29 includes 4×4 pixels 36 is shown.

In a scanning operation in the first embodiment, scanning is performed for each mask die 33. In the example of FIG. 4, the case of scanning a certain mask die 33 is shown. When all of the multiple beams 20 are used, m₁×n₁ sub-irradiation regions 29 are arranged in one irradiation region 34 in the x and y directions (two-dimensionally). The XY stage 105 is moved to a position where the multiple beams 20 can be emitted to the first mask die 33. While performing tracking deflection by the main deflector 208 to follow the movement of the XY stage 105, the inside of the mask die 33 is scanned (scanning operation) with the mask die 33 as the irradiation region 34 by the sub-deflector 209 in a tracking deflected state. Each beam configuring the multiple beams 20 is in charge of any one of the different sub-irradiation regions 29. At each shot, each beam irradiates one measurement pixel 28 corresponding to the same position in the assigned sub-irradiation region 29. In the example of FIG. 4, the sub-deflector 209 deflects each beam to irradiate the first measurement pixel 36 from the right side of the lowermost step in the assigned sub-irradiation region 29 in the first shot. In addition, irradiation of the first shot is performed Subsequently, the sub-deflector 209 collectively shifts the beam deflection positions of the entire multiple beams 20 in the y direction by one measurement pixel 36 to irradiate the first measurement pixel 36 from the right side of the second step from the bottom in the assigned sub-irradiation region 29 in the second shot. Similarly, the beams irradiate the first measurement pixel 36 from the right side of the third step from the bottom in the assigned sub-irradiation region 29 in the third shot. The beams irradiate the first measurement pixel 36 from the right side of the fourth step from the bottom in the assigned sub-irradiation region 29 in the fourth shot. Next, the sub-deflector 209 collectively shifts the beam deflection positions of the entire multiple beams 20 to the position of the second measurement pixel 36 from the right side of the lowermost step to sequentially irradiate the measurement pixels 36 in the y direction. This operation is repeated and all the measurement pixels 36 in one sub-irradiation region 29 are sequentially irradiated with one beam. In one shot, the multiple secondary electron beams 300 according to the same number of beam shots as the holes 22 at the maximum are detected at once by the multiple beams formed by passing through each hole 22 of the shaping aperture array substrate 203.

As described above, in the entire multiple beams 20, the mask die 33 is scanned as the irradiation region 34. However, each beam scans one corresponding sub-irradiation region 29. If scanning of one mask die 33 is completed, a next adjacent mask die 33 moves to become the irradiation region 34 and the next adjacent mask die 33 is scanned (scanned). This operation is repeated and scanning of each chip 332 is progressed. A secondary electron beam is emitted from the measurement pixel 36 irradiated with the beam every time the shot of the multiple beams 20 is performed and is detected by the multi-detector 222. The multi-detector 222 detects the secondary electron beam 11 emitted upward from each measurement pixel 36 for each measurement pixel 36 (or for each sub-irradiation region 29).

As described above, by performing scanning using the multiple beams 20, a scanning operation (measurement) can be performed at a higher speed than in the case of performing scanning with a single beam. Each mask die 33 may be scanned by a step and repeat operation or each mask die 33 may be scanned while the XY stage 105 is continuously moved. When the irradiation region 34 is smaller than the mask die 33, the scanning operation may be performed while the irradiation region 34 is moved in the mask die 33.

Here, the case of scanning the sub-irradiation region 29 in which an inter-beam pitch size becomes rectangular with one beam has been shown as an example. However, the present disclosure is not limited thereto. The sub-irradiation region 29 may be scanned with a plurality of beams. In any case, each pixel in the inspection region may be irradiated with any beam of the multiple beams 20 so that there is no irradiation leak.

When the substrate 101 is a mask substrate for exposure, a chip region of one chip formed on the mask substrate for exposure is divided into a plurality of stripe regions in the form of a strip with the size of the mask die 33 described above. For each stripe region, each mask die 33 may be scanned with the same scanning as the operation described above. Since the size of the mask die 33 in the mask substrate for exposure is a size before transferring, the size becomes four times larger than that of the mask die 33 of the semiconductor substrate. Therefore, when the irradiation region 34 is smaller than the mask die 33 in the mask substrate for exposure, the scanning operation for one chip increases (for example, four times). However, since a pattern for one chip is formed on the mask substrate for exposure, the number of scans can be smaller than that of a semiconductor substrate on which more chips than four chips are formed.

As described above, the image acquisition mechanism 150 scans the inspected substrate 101 on which the figure pattern has been formed by using the multiple beams 20 and detects the multiple secondary electron beams 300 emitted from the inspected substrate 101 due to irradiation of the multiple beams 20. Detection data of the secondary electrons (secondary electron image: measurement image: inspected image) from each measurement pixel 36 detected by the multi-detector 222 are output to the detection circuit 106 in order of measurement. In the detection circuit 106, analog detection data is converted into digital data by an A/D converter not shown in the drawings and is stored in the chip pattern memory 123. In this way, the image acquisition mechanism 150 acquires a measurement image of a pattern formed on the substrate 101. For example, when the detection data for one chip 332 is accumulated, the detection data is transferred to the comparison circuit 108 together with information showing each position from the position circuit 107 as chip pattern data.

FIGS. 5A and 5B are diagrams showing an example of an acquisition image in the first embodiment. In the example of FIG. 5A, an example of an image of a line pattern imaged by the image acquisition mechanism 150 is shown. In FIG. 5B, an example of the detection intensity of the line pattern image in FIG. 5A is shown.

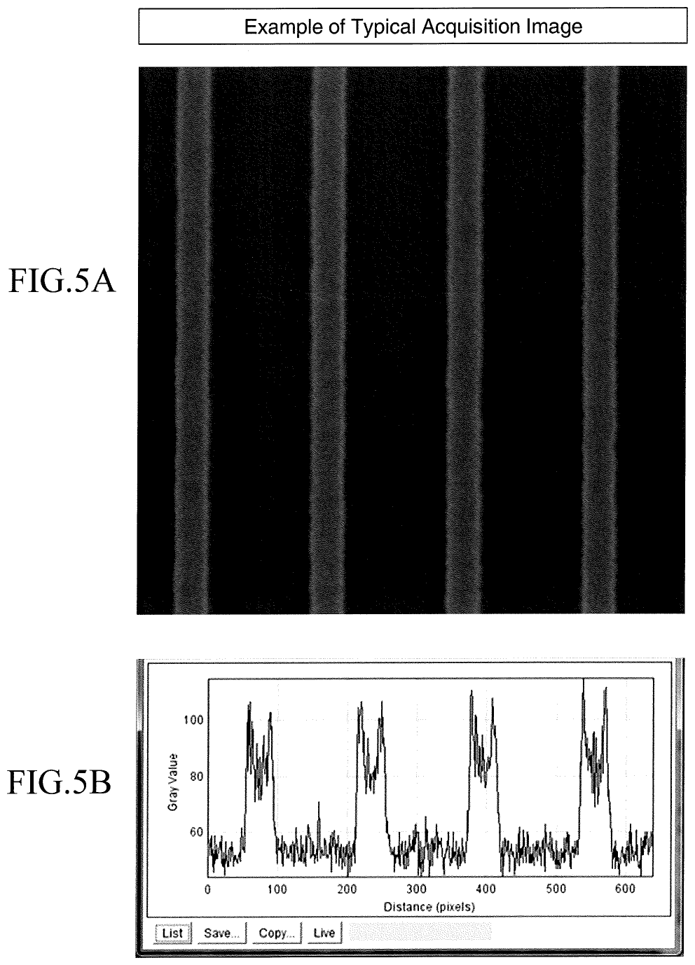

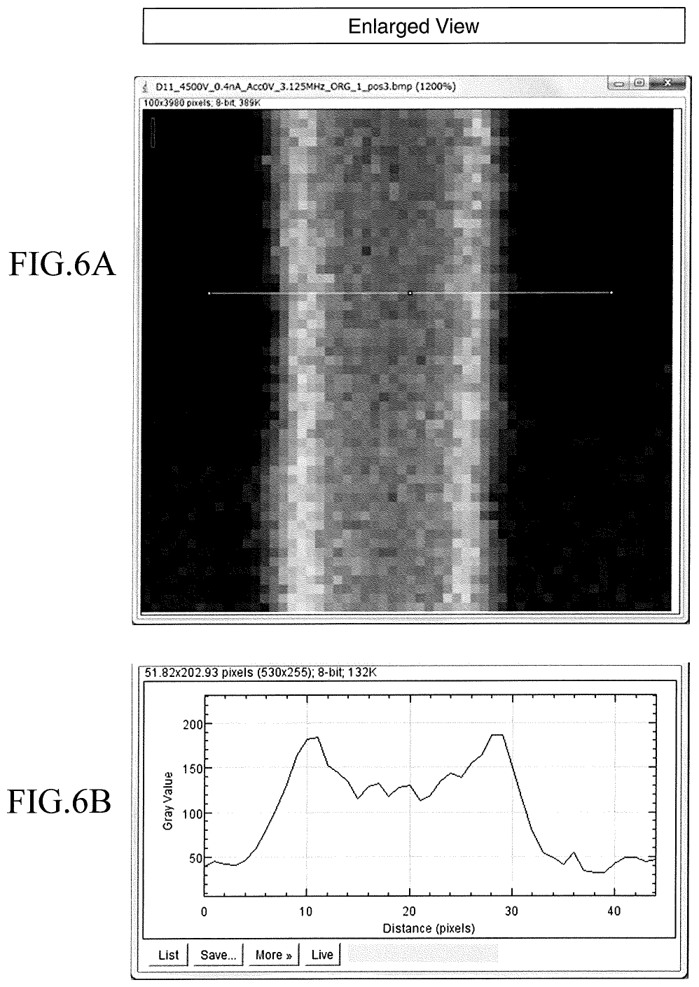

FIGS. 6A and 6B are diagrams showing an example of an enlarged view of an acquisition image in the first embodiment. In FIG. 6A, an example of an enlarged view of the image of the line pattern shown in FIG. 5A is shown. In FIG. 6B, an example of the detection intensity of the image of FIG. 6A is shown.

In the line pattern image shown in FIGS. 5A and 6A, the number of electrons in one pixel is, for example, about 50 to 500. Since shot noise can be approximated by roughly square root of the number of electrons, for example, in the case of an inspection apparatus with an average electron number of 100 per pixel, average 10 (=10%) noises exist. In the case where a defect detection threshold is set to be equal to or less than a 10% difference of a full range (25.6 gray difference in the case of 256 gray levels), a large number of pseudo defects caused by shot noise are generated. Of course, even if the threshold is increased for the probability distribution, it is inevitable to generate pseudo defects due to the shot noise. On the other hand, in the pattern inspection, a defect near an edge of the figure pattern may be detected. Therefore, in the first embodiment, an inspection target range is limited with the contour line of the figure pattern as a reference. Hereinafter, it will be specifically described.

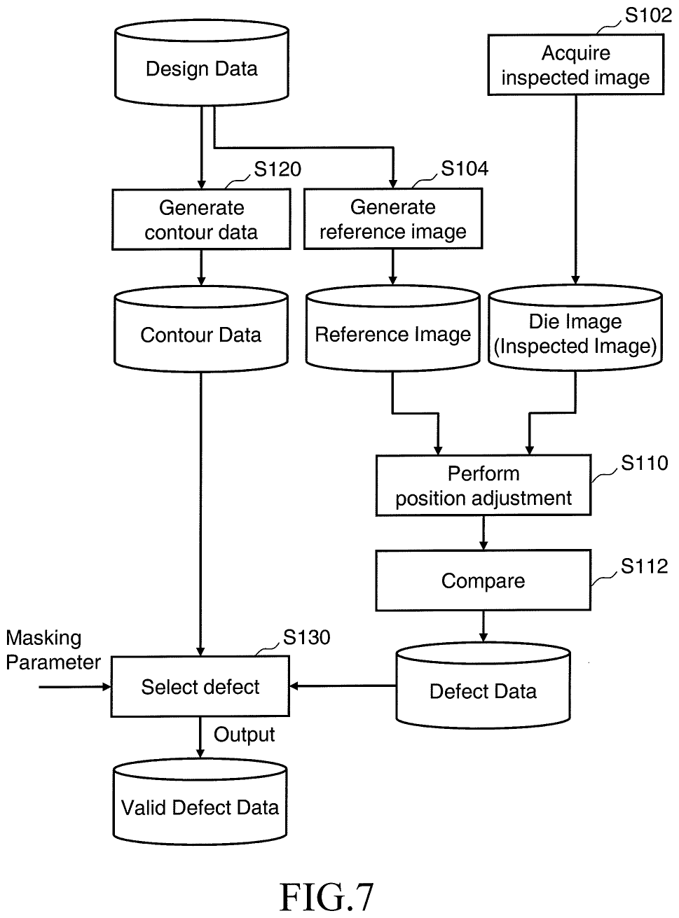

FIG. 7 is a flowchart showing main steps of an inspection method in the first embodiment. In FIG. 7, the inspection method in the first embodiment executes a series of steps including an inspected image acquisition step (S102), a reference image generation step (S104), a position adjustment step (S110), a comparison step (S112), a contour data generation step (S120), and a defect selection step (S130).

In the inspected image acquisition step (S102), the inspected image acquisition mechanism 150 acquires an inspected image of the figure pattern formed on the substrate 101 (inspection target object), using the multiple beams 20 (electron beams). The operation for acquiring a measurement image of the pattern formed on the substrate 101 is as described above.

In the reference image generation step (S104), the reference image generation circuit 112 (reference image generation unit) generates a reference image corresponding to the inspected image. The reference image generation circuit 112 generates a reference image for each frame region, on the basis of design data to be a basis for forming the pattern on the substrate 101 or design pattern data defined in exposure image data of the pattern formed on the substrate 101. For example, it is preferable to use the mask die 33 as the frame region. Specifically, the following operation is executed. First, the design pattern data is read from the storage device 109 through the control computer 110 and each figure pattern defined in the read design pattern data is converted into binary or multi-valued image data.

Here, in the figure defined in the design pattern data is, for example, a rectangle or a triangle is used as a basic figure. For example, diagram data in which a form, a size, a position, and the like of each pattern figure are defined by information such as the coordinates (x, y) at a reference position of the figure, a length of a side, and a figure code to be an identifier to distinguish a figure type such as the rectangle or the triangle is stored.

If the design pattern data to be the figure data is input to the reference image generation circuit 112, the data is expanded into data of each figure and a figure code showing the figure shape of the figure data, a figure dimension, and the like are interpreted. In addition, the data is expanded into binary or multi-valued design pattern image data as a pattern disposed in a square having a grid of a predetermined quantization size as a unit and is output. In other words, the design data is read, an occupation ratio occupied by the figure in the design pattern is operated for each square formed by virtually dividing the inspection region as a square with a predetermined dimension as a unit, and n-bit occupation ratio data is output. For example, it is preferable to set one square as one pixel. Assuming that one pixel has a resolution of 1/2⁸ (=1/256), a small region of 1/256 is allocated by the region of the figure disposed in the pixel to calculate the occupation ratio in the pixel. In addition, the data is output to the reference image generation circuit 112 as 8-bit occupation ratio data. The square (inspection pixel) may be matched with the pixel of the measurement data.

Next, the reference image generation circuit 112 performs appropriate filter processing on the design image data of the design pattern to be image data of the figure. Since optical image data as the measurement image is in a state in which the filter is operated by an optical system, in other words, in an analog state which continuously changes, the filter processing is performed on the design image data in which the image intensity (gray value) is image data on the design side of a digital value, so that the data can be matched with the measurement data. The image data of the generated reference image is output to the comparison circuit 108.

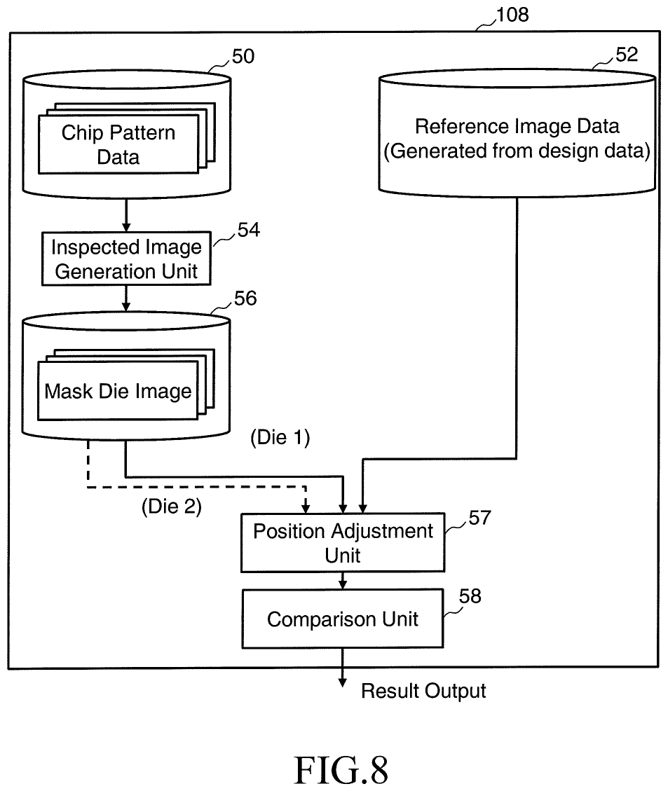

FIG. 8 is a configuration diagram showing an example of an internal configuration of the comparison circuit in the first embodiment. In FIG. 8, storage devices 50, 52, and 56 such as magnetic disk drives, an inspected image generation unit 54, a position adjustment unit 57, and a comparison unit 58 are disposed in the comparison circuit 108. Each “unit” such as the inspected image generation unit 54, the position adjustment unit 57, and the comparison unit 58 includes a processing circuit and an electric circuit, a computer, a processor, a circuit board, a quantum circuit, or a semiconductor device is included in the processing circuit. In addition, a common processing circuit (same processing circuit) may be used for each “unit”. Alternatively, a different processing circuit (separate processing circuit) may be used. Necessary input data or operated results in the inspected image generation unit 54, the position adjustment unit 57, and the comparison unit 58 are stored in a memory not shown in the drawings or the memory 118 each time.

In the comparison circuit 108, the transferred stripe pattern data (or the chip pattern data) is temporarily stored in the storage device 50 together with information showing each position from the position circuit 107. Further, the transferred reference image data is temporarily stored in the storage device 52.

Next, the inspected image generation unit 54 generates a frame image (inspected image) for each frame region (unit inspection region) of a predetermined size, using the stripe pattern data (or the chip pattern data). Here, for example, an image of the mask die 33 is generated as the frame image. However, the size of the frame region is not limited thereto. The generated frame image (for example, the mask die image) is stored in the storage device 56.

In the position adjustment step (S110), the position adjustment unit 57 reads the wafer die image to be the inspected image and the reference image corresponding to the wafer die image and adjusts positions of both the images in a unit of a sub-pixel smaller than the pixel 36. For example, the position adjustment may be performed by a method of least squares.

In the comparison step (S112), the comparison unit 58 compares the wafer die image (inspected image) with the reference image. The comparison unit 58 compares both the images for each pixel 36 according to a predetermined determination condition and determines presence or absence of a defect such as a shape defect, for example. For example, when a gray value difference for each pixel 36 is larger than a determination threshold Th, the defect is determined. In addition, a comparison result is output. The comparison result is output to the storage device 109 and is output to the defect selection circuit 132. As described above, at this stage, a large number of pseudo defects caused by the shot noise or the like are generated.

In the contour data generation step (S120), the contour data generation circuit 130 (contour data generation unit) generates contour data defining the contour line of the figure pattern. Specifically, the following operation is executed. The contour data generation circuit 130 reads the design pattern data to be a basis for generating the comparison target reference image stored in the storage device 109 and generates contour data defining the contour line of the figure pattern for each figure pattern. The generated contour data is output to the storage device 109 and is output to the defect selection circuit 132.

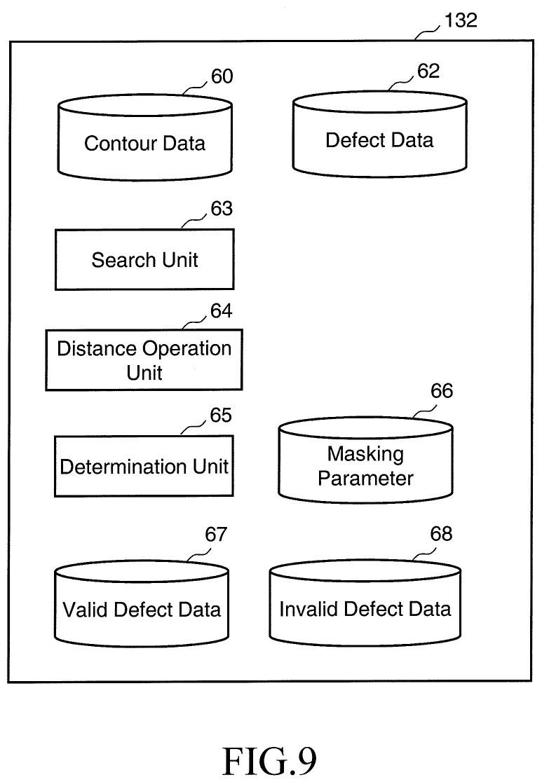

FIG. 9 is a configuration diagram showing an example of an internal configuration of the defect selection circuit in the first embodiment. In FIG. 9, storage devices 60, 62, 66, 67, and 68 such as magnetic disk drives, a search unit 63, a distance calculation unit 64, and a determination unit 65 are disposed in the defect selection circuit 132. Each “unit” such as the search unit 63, the distance calculation unit 64, and the determination unit 65 includes a processing circuit and an electric circuit, a computer, a processor, a circuit board, a quantum circuit, or a semiconductor device is included in the processing circuit. In addition, a common processing circuit (same processing circuit) may be used for each “unit”. Alternatively, a different processing circuit (separate processing circuit) may be used. Necessary input data or operated results in the search unit 63, the distance calculation unit 64, and the determination unit 65 are stored in a memory not shown in the drawings or the memory 118 each time.

In the defect selection step (S130), the defect selection circuit 132 (defect selection unit) selects a defect within a range preset on the basis of the contour line of the figure pattern as a valid defect, from at least one defect determined to be the defect by the comparison, using the contour data.

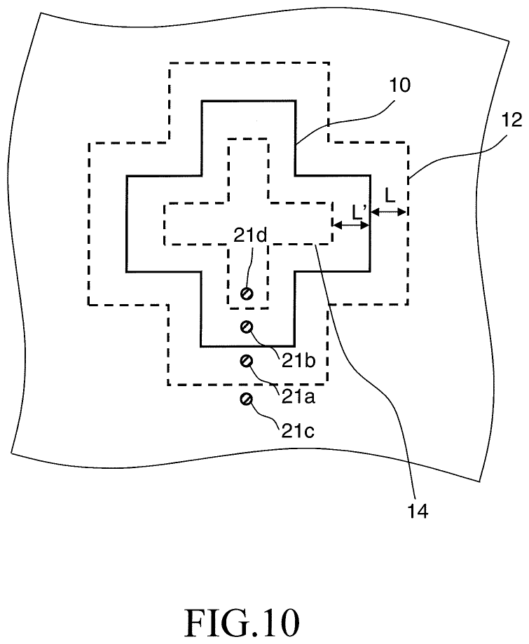

FIG. 10 is a diagram showing an example of a defect selection region in the first embodiment. In FIG. 10, an outer circumferential line 12 externally separated from a contour line 10 of the figure pattern by a normal distance L as a valid distance and an inner circumferential line 14 internally separated from the contour line 10 of the figure pattern by a normal distance L′ as a valid distance are shown. In the first embodiment, a defect 21a generated in a region between the contour line 10 of the figure pattern and the outer circumferential line 12 is selected as a valid defect. Similarly, a defect 21b generated in a region between the contour line 10 of the figure pattern and the inner circumferential line 14 is selected as a valid defect. On the other hand, a defect 21c generated in a region outside the outer circumferential line 12 is selected as an invalid defect. Similarly, a defect 21d generated in a region inside the inner circumferential line 14 is selected as an invalid defect. An operation of the selection processing is specifically described.

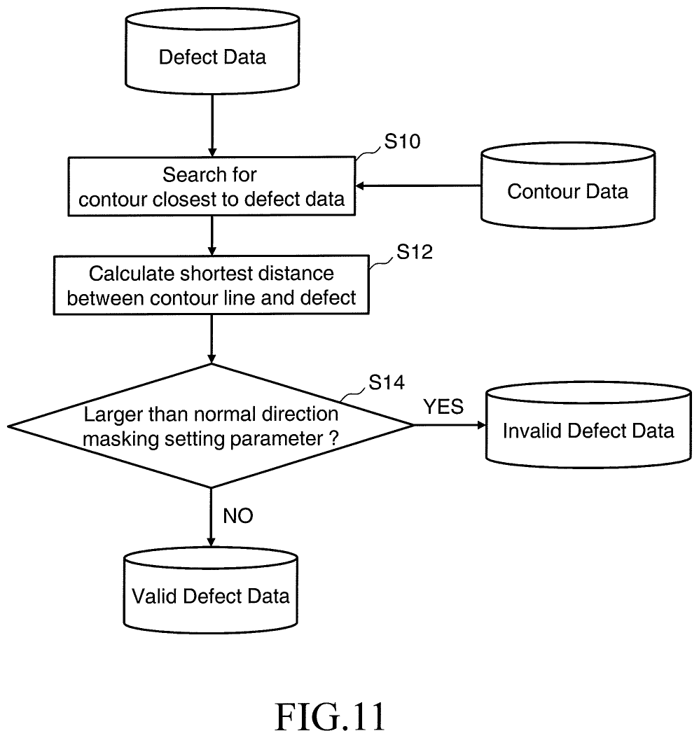

FIG. 11 is a flowchart showing internal steps of the defect selection step in the first embodiment. In FIG. 11, the defect selection step (S130) executes a series of steps including a search step (S10), a shortest distance calculation step (S12), and a determination step (S14) as the internal steps.

In the search step (S10), the search unit 63 searches for the contour line closest to the defect position determined to be the defect, using the contour data.

FIG. 12 is a diagram showing an example of a defect and a surrounding contour line in the first embodiment. In the example of FIG. 12, a contour line 10a of a rectangular pattern and a part of a contour line 10b of a polygonal pattern are shown as an example in the vicinity of a defect 21. The search unit 63 spreads a search circle around a defect position. In addition, the search unit 63 searches for a contour line closest to the defect position. In the example of FIG. 12, the case where the defect 21 is located outside the figure pattern is shown. However, the present disclosure is not limited thereto. The defect 21 may be located inside the figure pattern.

In the shortest distance calculation step (S12), the distance calculation unit 64 calculates the shortest distance from the defect position to the contour line. In principle, the distance calculation unit 64 calculates the distance (normal distance) in the normal direction with respect to the contour line from the defect position to the searched contour line as the shortest distance. As shown in the example of FIG. 12, for example, in the contour line 10a of the rectangular pattern, the normal distance to the contour line is calculated as the shortest distance. However, in the contour line 10b of the polygonal pattern, a corner where the contour lines are connected first appears. In this case, the distance to the corner may be calculated as the shortest distance.

In the determination step (S14), the determination unit 65 determines whether the shortest distance from the defect position to the contour line is within a preset valid distance, for each detected defect. A parameter (masking parameter) showing the valid distance is stored in advance in the storage device 66. Hereinafter, it will be specifically described.

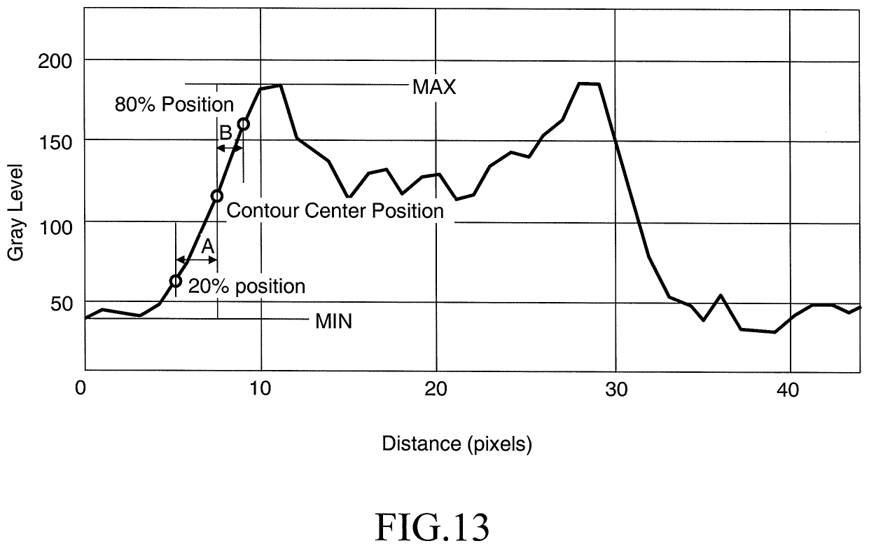

FIG. 13 shows an example of a detection intensity distribution of an inspected image in the first embodiment. In FIG. 13, in the case where a maximum value of a detection intensity distribution in a rising portion (or a falling portion) of a detection intensity distribution showing an edge of the figure pattern is set as 100 and a minimum value is set as zero, if an intermediate level of 50% is set as the edge (contour line) of the figure pattern, a distance A from the edge (contour line) of the figure pattern to a level of 20% and a distance B from the edge (contour line) of the figure pattern to a level of 80% are preferably set as valid distances (masking parameters). For example, it is preferable to set a distance of 1 to 5 pixels (for example, 2 pixels) of the reference image as a masking parameter.

If the shortest distance from the defect position to the contour line is smaller than the preset valid distance (if the defect position is close to the contour line), the determination unit 65 stores the data of the defect as a valid defect in the storage device 67. If the shortest distance from the defect position to the contour line is larger than the preset valid distance (if the defect position is not close to the contour line), the determination unit 65 stores the data of the defect as an invalid defect in the storage device 68. By the above determination processing, a valid defect within a range preset on the basis of the contour line of the figure pattern is selected from at least one defect detected. In addition, a selection result is output. The selection result may be output to the storage device 109, the monitor 117, or the memory 118 or may be output from the printer 119.

As described above, by narrowing down the defects to the defects within the valid distance on the basis of the contour line inside and outside the figure pattern, the defect data of the region unnecessary for the inspection is eliminated. As a result, the pseudo defects caused by the shot noise and the like can be greatly reduced. Particularly, as shown in FIG. 13, by setting a range of an intermediate portion of the rising portion (or the falling portion) of the detection intensity distribution showing the edge of the figure pattern as a range within the valid distance from the contour line, the pseudo defects caused by the shot noise can be substantially eliminated.

In the above example, as shown in FIG. 7, an example of the case of performing the die to database inspection as the inspection method has been described. However, the inspection method is not limited to the die to database inspection.

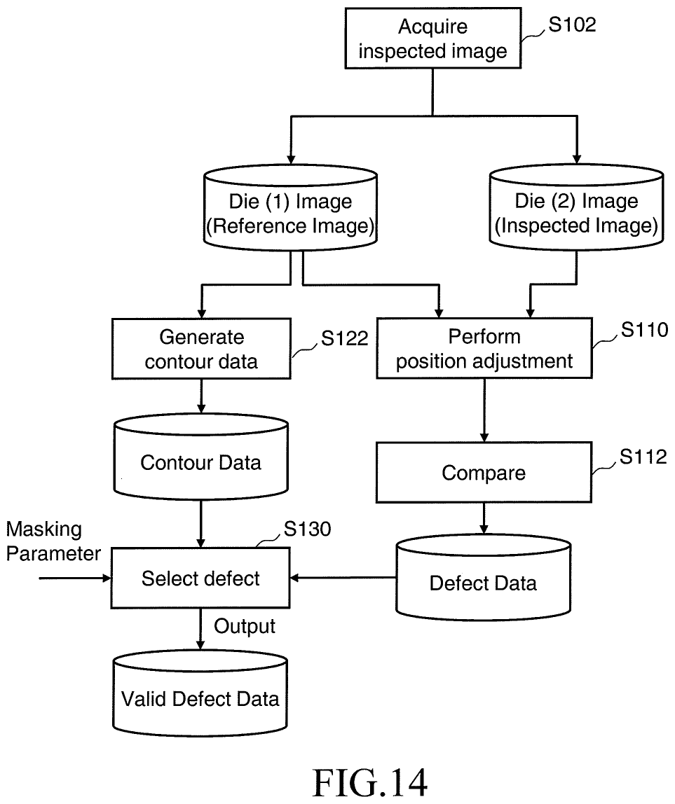

FIG. 14 is a flowchart showing main steps of a modification of the inspection method in the first embodiment. In FIG. 14, an example of the case of performing a die to die inspection as the inspection method is shown. In FIG. 14, a modification of the inspection method in the first embodiment executes a series of steps including an inspected image acquisition step (S102), a position adjustment step (S110), a comparison step (S112), a contour data generation step (S122), and a defect selection step (S130).

The contents of the inspected image acquisition step (S102) are the same as those described above. In the die to die inspection, frame images of the die on which the same pattern is formed are compared. Therefore, a mask die image of a region of a part of the chip (wafer die) 332 to be a die (1) and a mask die image of a corresponding region of another chip (wafer die) 332 to be a die (2) are used.

In the position adjustment step (S110), the position adjustment unit 57 reads the wafer die image of the die (1) and the wafer die image of the die (2) to be the inspected images and adjusts positions of both the images in a unit of a sub-pixel smaller than the pixel 36. For example, the position adjustment may be performed by a method of least squares.

In the comparison step (S112), the comparison unit 58 compares the wafer die image of the die (1) with the wafer die image of the die (2). Here, one of the wafer die image of the die (1) and the wafer die image of the die (2) becomes the reference image (for example, the die (1)) and the other becomes the inspected image (for example, the die (2)). A comparison method may be the same as that in the case of the die to database inspection. In addition, a comparison result is output. The comparison result is output to the storage device 109 and is output to the defect selection circuit 132. As described above, at this stage, a large number of pseudo defects caused by the shot noise or the like are generated.

In the contour data generation step (S122), the contour data generation circuit 130 (contour data generation unit) generates contour data defining the contour line of the figure pattern. Specifically, the following operation is executed. In the case of performing the die to die inspection, the design pattern data often does not exist. Therefore, the contour data generation circuit 130 reads the wafer die image of the die (1) used as the reference image from the storage device 56 in the comparison circuit 108 and extracts the figure pattern. In addition, the contour data generation circuit 130 generates contour data defining the contour line of the figure pattern, for each extracted figure pattern. As shown in FIG. 13, the position of the contour line may be a gray level position of 50% of the rising portion (or the falling portion) of the detection intensity distribution showing the edge of the figure pattern. The generated contour data is output to the storage device 109 and is output to the defect selection circuit 132.

The contents of the defect selection step (S130) are the same as those described above. As such, defect selection using the contour line can also be applied to the die to die inspection.

As described above, according to the first embodiment, even in the case where the large noise such as the shot noise occurs when the defect inspection is performed using the image acquired by using the electron beam, occurrence of the pseudo defects that are unnecessary for detection can be reduced.

### Second Embodiment

In the first embodiment, the configuration in which a region of a valid defect is limited after a defect is detected has been described. In a second embodiment, a configuration in which an inspection is performed after an inspection region is limited will be described. Points not specifically described below may be the same as those of the first embodiment.

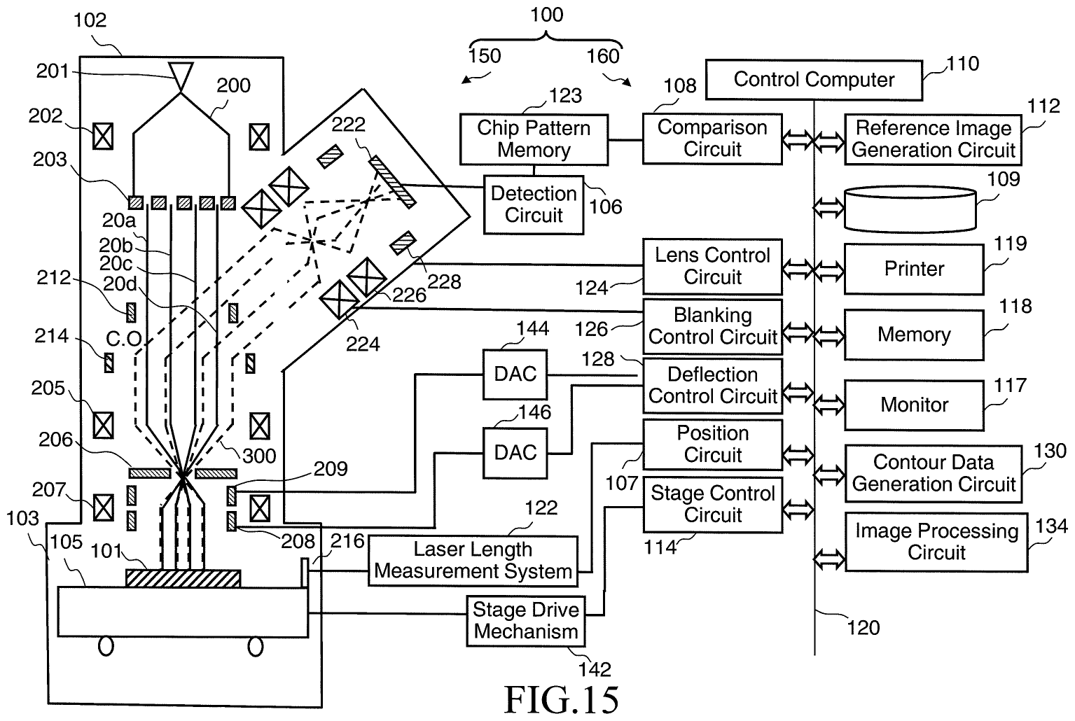

FIG. 15 is a configuration diagram showing a configuration of a pattern inspection apparatus in a second embodiment. FIG. 15 is the same as FIG. 1 except that an image processing circuit 134 is disposed instead of a defect selection circuit 132.

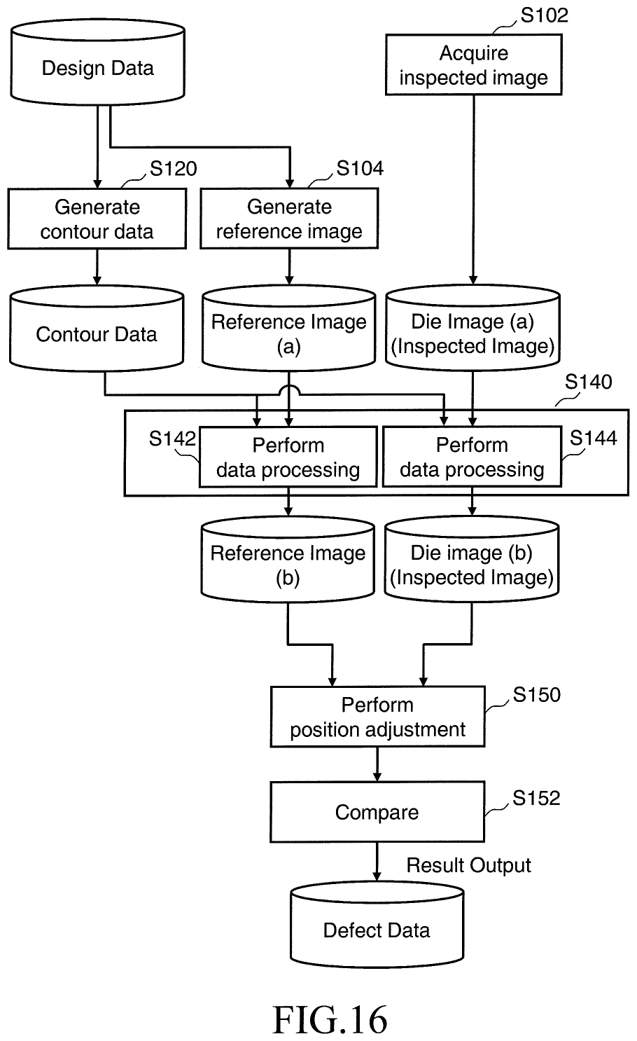

FIG. 16 is a flowchart showing main steps of an inspection method in the second embodiment. In FIG. 16, the inspection method in the second embodiment executes a series of steps including an inspected image acquisition step (S102), a reference image generation step (S104), a contour data generation step (S120), a data processing step (S140), a position adjustment step (S150), and a comparison step (S152). The data processing step (S140) executes a reference image data processing step (S142) and an inspected image data processing step (S144) as internal steps.

The contents of each step of the inspected image acquisition step (S102), the reference image generation step (S104), and the contour data generation step (S120) are the same as those in the first embodiment. However, in the inspected image acquisition step (S102), for example, at a stage where detection data for one chip 332 is accumulated, the detection data is transferred to the image processing circuit 134 together with information showing each position from a position circuit 107 as chip pattern data. Further, in the reference image generation step (S104), the generated reference image is transferred to the image processing circuit 134. Further, the generated contour data is output to a storage device 109 and is output to the image processing circuit 134.

In the data processing step (S140), the image processing circuit 134 (image processing unit) processes the inspected image and the reference image using the contour data.

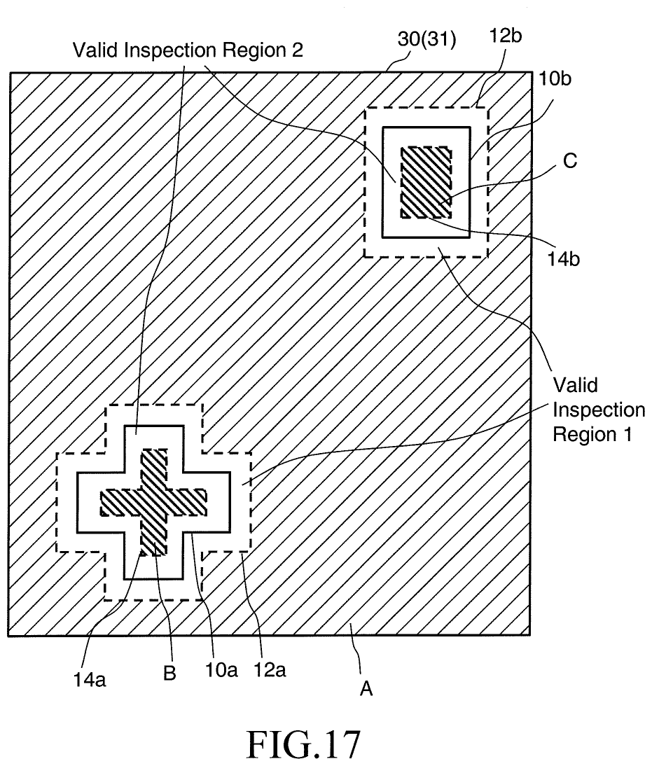

FIG. 17 is a diagram showing an example of a valid inspection region in the second embodiment. In the example of FIG. 17, the case where a cross-shaped figure pattern shown by a contour line 10a and a rectangular figure pattern shown by a contour line 10b are disposed in a reference image 31 is shown. In FIG. 17, an outer circumferential line 12a externally separated from a contour line 10a of the figure pattern by a normal distance L as a valid distance and an inner circumferential line 14a internally separated from the contour line 10a of the figure pattern by a normal distance L′ as a valid distance are shown. Likewise, an outer circumferential line 12b externally separated from a contour line 10b of the figure pattern by a normal distance L as a valid distance and an inner circumferential line 14b internally separated from the contour line 10b of the figure pattern by a normal distance L′ as a valid distance are shown. In the second embodiment, a region between the contour line 10a of the figure pattern and the outer circumferential line 12a, a region between the contour line 10a of the figure pattern and the inner circumferential line 14a, a region between the contour line 10b of the figure pattern and the outer circumferential line 12b, and a region between the contour line 10b of the figure pattern and the inner circumferential line 14b are set as a valid inspection region. Therefore, the image processing circuit 134 processes an inspected image 30 and the reference image 31 to exclude a region outside a range preset on the basis of the contour line from the inspection region. In the example of FIG. 17, for the inspected image 30 and the reference image 31, a region A outside the outer circumferential lines 12a and 12b is excluded from the valid inspection region. A region B inside the inner circumferential line 14a and a region C inside the inner circumferential line 14b are excluded from the valid inspection region. Therefore, the following operation is executed.

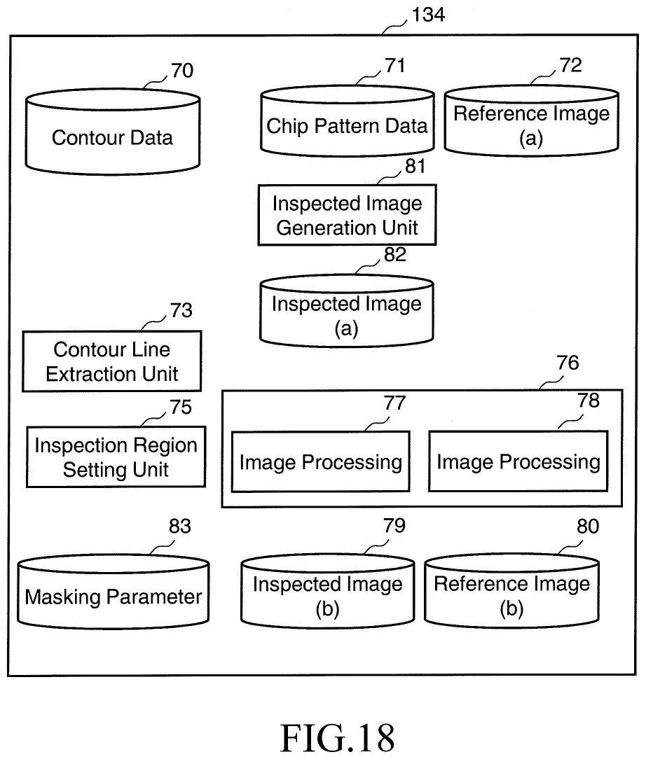

FIG. 18 is a configuration diagram showing an example of an internal configuration of the image processing circuit in the second embodiment. In FIG. 18, storage devices 70, 71, 72, 79, 80, 82, and 83 such as magnetic disk drives, a contour line extraction unit 73, an inspection region setting unit 75, a data processing unit 76, and an inspected image generation unit 81 are disposed in the image processing circuit 134. In the data processing unit 76, image processing units 77 and 78 are disposed. Each “unit” such as the contour line extraction unit 73, the inspection region setting unit 75, the data processing unit 76 (image processing units 77 and 78), and the inspected image generation unit 81 includes a processing circuit and an electric circuit, a computer, a processor, a circuit board, a quantum circuit, or a semiconductor device is included in the processing circuit. In addition, a common processing circuit (same processing circuit) may be used for each “unit”. Alternatively, a different processing circuit (separate processing circuit) may be used. Necessary input data or operated results in the contour line extraction unit 73, the inspection region setting unit 75, the data processing unit 76 (image processing units 77 and 78), and the inspected image generation unit 81 are stored in a memory not shown in the drawings or a memory 118 each time.

In the image processing circuit 134, the input contour data is stored in the storage device 70. Further, transferred stripe pattern data (or chip pattern data) is temporarily stored in the storage device 71 together with information showing each position from the position circuit 107. Further, the transferred reference image data (reference image (a)) is temporarily stored in the storage device 72. Further, a parameter (masking parameter) showing the valid distance is stored in advance in the storage device 83.

Next, the inspected image generation unit 81 generates a frame image (inspected image) for each frame region (unit inspection region) of a predetermined size, using the stripe pattern data (or the chip pattern data). Here, for example, an image of the mask die 33 is generated as the frame image. However, the size of the frame region is not limited thereto. The generated frame image (for example, the mask die image) (inspected image (a)) is stored in the storage device 82.

In the contour line extraction step, the contour line extraction unit 73 refers to the contour data to extract a contour line 10 of a figure pattern to be disposed in the target reference image (a) (before data processing) for each reference image (a).

In the inspection region setting step, the inspection region setting unit 75 sets a valid inspection region 1 between the contour line 10 of the figure pattern and an outer circumferential line 12 separated by a valid distance A shown by a masking parameter in a normal direction of the contour line 10 along the contour line 10 of the figure pattern and a valid inspection region 2 between the contour line 10 of the figure pattern and an inner circumferential line 14 separated by a valid distance B in a normal direction of the contour line 10 along the contour line 10 of the figure pattern, for each figure pattern.

In the reference image data processing step (S142), the image processing unit 78 generates a reference image (b) by processing a pixel value of a region deviated from the valid inspection regions 1 and 2 of the target reference image (a) with a predetermined value, for each reference image (a) (image before data processing). A pixel value of the region deviated from the valid inspection regions 1 and 2 is set to zero, for example. Data of the processed reference image (b) is stored in the storage device 80 and is output to a comparison circuit 108.

In the inspected image data processing step (S144), the image processing unit 77 generates an inspected image (b) by processing a pixel value of a region deviated from the valid inspection regions 1 and 2 of the target inspected image (a) with a predetermined value, for each inspected image (a) (image before data processing). A pixel value of the region deviated from the valid inspection regions 1 and 2 is set to zero, for example. Data of the processed inspected image (b) is stored in the storage device 79 and is output to the comparison circuit 108. Here, a difference value between the pixel value of the reference image (b) and the pixel value of the inspected image (b) may be set to zero, for the region deviated from the valid inspection regions 1 and 2.

In the comparison circuit 108, the processed reference image (b) is stored in a storage device 52. Further, the processed inspected image (b) is stored in a storage device 56.

Here, in the second embodiment, since the inspected image (a) is generated in the image processing circuit 134, a storage device 50 and an inspected image generation unit 54 in the comparison circuit 108 in FIG. 8 may be omitted. Alternatively, after the inspected image is generated by the inspected image generation unit 54 in the comparison circuit 108, the inspected image may be transferred to the image processing circuit 134. In this case, the storage device 71 and the inspected image generation unit 81 in the image processing circuit 134 may be omitted.

In the position adjustment step (S150), a position adjustment unit 57 reads a wafer die image to be the inspected image (b) and the reference image (b) corresponding to the wafer die image and adjusts positions of both the images in a unit of a sub-pixel smaller than a pixel 36. For example, the position adjustment may be performed by a method of least squares.

In the comparison step (S112), a comparison unit 58 compares the wafer die image (inspected image (b)) with the reference image (b). The comparison unit 58 compares both the images for each pixel 36 according to a predetermined determination condition and determines presence or absence of a defect such as a shape defect, for example. For example, when a gray value difference for each pixel 36 is larger than a determination threshold Th, the defect is determined. In addition, a comparison result is output. The comparison result may be output to the storage device 109, a monitor 117, or the memory 118 or may be output from a printer 119.

As described above, by narrowing down the inspection regions to the regions (valid inspection regions 1 and 2) within the valid distance on the basis of the contour line inside and outside the figure pattern, defect data of the region unnecessary for the inspection is eliminated. As a result, the pseudo defects caused by the shot noise and the like can be greatly reduced. Particularly, as shown in FIG. 13, by setting a range of an intermediate portion of the rising portion (or the falling portion) of the detection intensity distribution showing the edge of the figure pattern as a range within the valid distance from the contour line, the pseudo defects caused by the shot noise can be substantially eliminated.

Here, in the above example, as shown in FIG. 16, an example of the case of performing die to database inspection as the inspection method has been described. However, the inspection method is not limited to the die to database inspection.

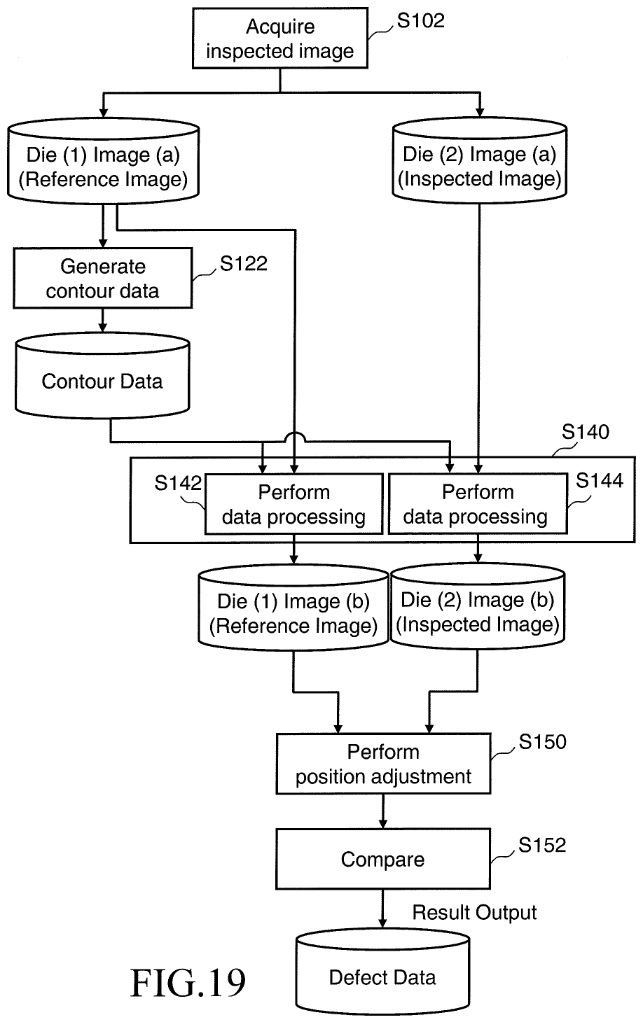

FIG. 19 is a flowchart showing main steps of a modification of the inspection method in the second embodiment. In FIG. 19, an example of the case of performing a die to die inspection as the inspection method is shown. In FIG. 19, the modification of the inspection method in the second embodiment executes a series of steps including an inspected image acquisition step (S102), a contour data generation step (S122), a data processing step (S140), a position adjustment step (S150), and a comparison step (S152).

The contents of the inspected image acquisition step (S102) are the same as those described above. However, in the inspected image acquisition step (S102), for example, at a stage where detection data for one chip 332 is accumulated, the detection data is transferred to the image processing circuit 134 together with information showing each position from a position circuit 107 as chip pattern data.

In the image processing circuit 134, the transferred stripe pattern data (or the chip pattern data) is temporarily stored in the storage device 71 together with information showing each position from the position circuit 107. Further, a parameter (masking parameter) showing the valid distance is stored in advance in the storage device 83.

Next, the inspected image generation unit 81 generates a frame image (inspected image) for each frame region (unit inspection region) of a predetermined size, using the stripe pattern data (or the chip pattern data). Here, for example, an image of the mask die 33 is generated as the frame image. However, the size of the frame region is not limited thereto. The generated frame image (for example, the mask die image) (inspected image (a)) is stored in the storage device 82.

In the die to die inspection, frame images of the die on which the same pattern is formed are compared. Therefore, a mask die image of a region of a part of the chip (wafer die) 332 to be a die (1) and a mask die image of a corresponding region of another chip (wafer die) 332 to be a die (2) are used.

In the contour data generation step (S122), the contour data generation circuit 130 (contour data generation unit) generates contour data defining the contour line of the figure pattern. Specifically, the following operation is executed. In the case of performing the die to die inspection, the design pattern data often does not exist. Therefore, the contour data generation circuit 130 reads the wafer die image (die (1) image (a)) of the die (1) used as the reference image (a) from the storage device 82 in the image processing circuit 134 and extracts a figure pattern. In addition, the contour data generation circuit 130 generates contour data defining the contour line of the figure pattern, for each extracted figure pattern. As shown in FIG. 13, the position of the contour line may be a gray level position of 50% of the rising portion (or the falling portion) of the detection intensity distribution showing the edge of the figure pattern. The generated contour data is output to the storage device 109 and is output to the image processing circuit 134.

In the image processing circuit 134, the input contour data is stored in the storage device 70.

In the data processing step (S140), the image processing circuit 134 (image processing unit) processes the wafer die image (die (2) image (a)) of the die (2) to be the inspected image and the wafer die image (die (1) image (a)) of the die (1) to be the reference image, using the contour data.

In the contour line extraction step, the contour line extraction unit 73 refers to the contour data to extract a contour line 10 of a figure pattern to be disposed in the target reference image (a) (before data processing) for each reference image (a).

In the inspection region setting step, the inspection region setting unit 75 sets a valid inspection region 1 between the contour line 10 of the figure pattern and an outer circumferential line 12 separated by a valid distance A shown by a masking parameter in a normal direction of the contour line 10 along the contour line 10 of the figure pattern and a valid inspection region 2 between the contour line 10 of the figure pattern and an inner circumferential line 14 separated by a valid distance B in a normal direction of the contour line 10 along the contour line 10 of the figure pattern, for each figure pattern.

In the reference image data processing step (S142), the image processing unit 78 generates a die (1) image (b) by processing a pixel value of a region deviated from the valid inspection regions 1 and 2 of the target die (1) image (a) with a predetermined value, for each wafer die image (die (1) image (a)) of the die (1) to be the reference image. A pixel value of the region deviated from the valid inspection regions 1 and 2 is set to zero, for example. Data of the processed die (1) image (b) is stored in the storage device 80 and is output to the comparison circuit 108.

In the inspected image data processing step (S144), the image processing unit 77 generates a die (2) image (b) by processing a pixel value of a region deviated from the valid inspection regions 1 and 2 of the target die (2) image (a) with a predetermined value, for each wafer die image (die (2) image (a)) of the die (2) to be the inspected image. A pixel value of the region deviated from the valid inspection regions 1 and 2 is set to zero, for example. Data of the processed die (2) image (b) is stored in the storage device 79 and is output to the comparison circuit 108. Here, a difference value between the pixel value of the reference image (b) (die (1) image (b)) and the pixel value of the inspected image (b) (die (2) image (b)) may be set to zero, for the region deviated from the valid inspection regions 1 and 2.

In the comparison circuit 108, the processed reference image (b) (die (1) image (b)) is stored in the storage device 52. Further, the processed inspected image (b) (die (2) image (b)) is stored in the storage device 56.

The contents of the position adjustment step (S150) and the comparison step (S152) are the same as those in the case of the die to database inspection. As such, defect selection using the contour line can also be applied to the die to die inspection.

As described above, according to the second embodiment, even in the case where the large noise such as the shot noise occurs when the defect inspection is performed using the image acquired by using the electron beam, occurrence of the pseudo defects that are unnecessary for detection can be reduced.

### Third Embodiment

In the second embodiment, the case where a region simply deviated from a valid distance is excluded from an inspection region has been described. However, the present disclosure is not limited thereto. There are cases where it is desired to detect a large defect at a position in the vicinity deviated outward from an outer circumferential line 12. There are cases where it is desired to detect a large defect at a position in the vicinity deviated inward from an inner circumferential line 14. However, if all defects deviated from valid inspection regions 1 and 2 are detected, pseudo defects frequently occur. Therefore, in a third embodiment, a configuration capable of detecting large defects in the vicinity of the outer circumferential line 12 and in the vicinity of the inner circumferential line 14 while reducing pseudo defects at positions deviated from the valid inspection regions 1 and 2 will be described. In the third embodiment, the concept of the second embodiment in which an inspection region is narrowed down on the basis of a contour line 10 is combined with the concept of weighting according to a distance from the contour line 10.

A configuration of an inspection apparatus 100 in the third embodiment is the same as that of FIG. 15. Further, a flowchart showing main steps of an inspection method in the third embodiment is the same as that in FIG. 16 for a die to database inspection. A die to die inspection is the same as that in FIG. 19. Contents other than points specifically described below are the same as those in the second embodiment.

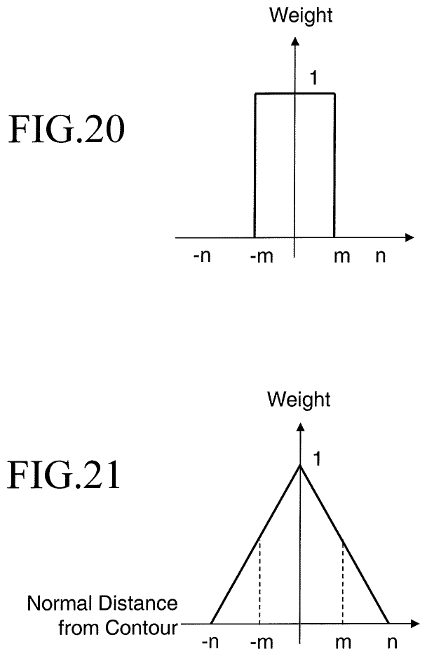

FIG. 20 is a diagram showing a relation between a distance from a contour line and weighting of a defect in a comparative example (second embodiment) of the third embodiment. In FIG. 20, a length axis shows a weight (ratio) of the defect and a width axis shows a normal distance from the contour line. As shown in FIG. 20, in the comparative example (second embodiment) of the third embodiment, in a region within a valid distance m from the contour line 10 of the figure pattern, all defects to be detected are detected with the same weight (ratio). In this case, it is difficult to detect a large defect at the position in the vicinity deviated outward from the outer circumferential line 12. Similarly, it is difficult to detect a large defect at the position in the vicinity deviated inward from the inner circumferential line 14. Therefore, in the third embodiment, a data processing method is changed as follows.

In a data processing step (S140), an image processing circuit 134 (image processing unit) processes an inspected image (a) and a reference image (a) using contour data to weight data of the inspected image (a) and data of the reference image (a), according to a distance from the contour line 10.

FIG. 21 is a diagram showing an example of a relation between a distance from a contour line and weighting of a defect in the third embodiment. In FIG. 21, a length axis shows a weight (ratio) of the defect and a width axis shows a normal distance from the contour line. In the example of FIG. 21, the weighting of the defect is lowered (changed) according to the distance from the contour line with a primary proportion (straight line) with a weight 1 (100%) on the contour line 10. For example, the inspected image and the reference image are processed so that the weight becomes zero at a distance n from the contour line 10 extending further outward beyond an outside valid distance m from the contour line 10. Likewise, the inspected image and the reference image are processed so that the weight becomes zero at a distance n from the contour line 10 extending further inward beyond an inside valid distance m from the contour line 10. In this case, the following operation is executed.

In a reference image data processing step (S142), an image processing unit 78 generates the reference image (b) by executing filter processing (data processing) on all data of the target reference image (a), using a filter function in which the weight becomes zero at the distance n in the normal direction from the position of the contour line with the primary proportion, for each reference image (a) (image before data processing). Data of the processed reference image (b) is stored in the storage device 80 and is output to a comparison circuit 108.

In an inspected image data processing step (S144), an image processing unit 77 generates the inspected image (b) by executing filter processing (data processing) on all data of the target inspected image (a), using a filter function in which the weight becomes zero at the distance n in the normal direction from the position of the contour line with the primary proportion, for each inspected image (a) (image before data processing). Data of the processed inspected image (b) is stored in the storage device 79 and is output to the comparison circuit 108.

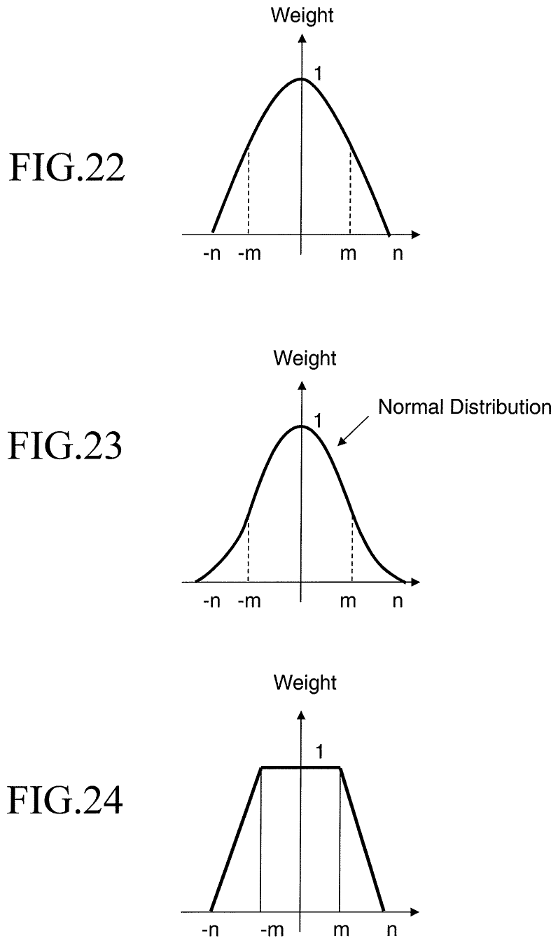

FIG. 22 is a diagram showing another example of a relation between a distance from a contour line and weighting of a defect in the third embodiment. In FIG. 22, a length axis shows a weight (ratio) of the defect and a width axis shows a normal distance from the contour line. In the example of FIG. 22, the weighting of the defect is lowered (changed) according to the distance from the contour line with a secondary proportion (parabola) with a weight 1 (100%) on the contour line 10. For example, the inspected image and the reference image are processed so that the weight becomes zero at a distance n from the contour line 10 extending further outward beyond an outside valid distance m from the contour line 10. Likewise, the inspected image and the reference image are processed so that the weight becomes zero at a distance n from the contour line 10 extending further inward beyond an inside valid distance m from the contour line 10. In this case, the following operation is executed.

In the reference image data processing step (S142), the image processing unit 78 generates the reference image (b) by executing filter processing (data processing) on all data of the target reference image (a), using a filter function in which the weight becomes zero at the distance n in the normal direction from the position of the contour line with the secondary proportion, for each reference image (a) (image before data processing). Data of the processed reference image (b) is stored in the storage device 80 and is output to a comparison circuit 108.

In the inspected image data processing step (S144), the image processing unit 77 generates the inspected image (b) by executing filter processing (data processing) on all data of the target inspected image (a), using a filter function in which the weight becomes zero at the distance n in the normal direction from the position of the contour line with the secondary proportion, for each inspected image (a) (image before data processing). Data of the processed inspected image (b) is stored in the storage device 79 and is output to the comparison circuit 108.

FIG. 23 is a diagram showing another example of a relation between a distance from a contour line and weighting of a defect in the third embodiment. In FIG. 23, a length axis shows a weight (ratio) of the defect and a width axis shows a normal distance from the contour line. In the example of FIG. 23, the weighting of the defect is lowered (changed) according to the distance from the contour line with a normal distribution with a weight 1 (100%) on the contour line 10. For example, the inspected image and the reference image are processed so that the weight becomes zero at a distance n from the contour line 10 extending further outward beyond an outside valid distance m from the contour line 10. Likewise, the inspected image and the reference image are processed so that the weight becomes zero at a distance n from the contour line 10 extending further inward beyond an inside valid distance m from the contour line 10. In this case, the following operation is executed.

In the reference image data processing step (S142), the image processing unit 78 generates the reference image (b) by executing filter processing (data processing) on all data of the target reference image (a), using a filter function in which the weight becomes zero at the distance n in the normal direction from the position of the contour line along the normal distribution, for each reference image (a) (image before data processing). Data of the processed reference image (b) is stored in the storage device 80 and is output to a comparison circuit 108.

In the inspected image data processing step (S144), the image processing unit 77 generates the inspected image (b) by executing filter processing (data processing) on all data of the target inspected image (a), using a filter function in which the weight becomes zero at the distance n in the normal direction from the position of the contour line along the normal distribution, for each inspected image (a) (image before data processing). Data of the processed inspected image (b) is stored in the storage device 79 and is output to the comparison circuit 108.

FIG. 24 is a diagram showing another example of a relation between a distance from a contour line and weighting of a defect in the third embodiment. In FIG. 24, a length axis shows a weight (ratio) of the defect and a width axis shows a normal distance from the contour line. In the example of FIG. 24, the weight 1 (100%) is set from the contour line 10 to the outside valid distance m and the weight of the defect is lowered (changed) according to the distance from the valid distance m. For example, the inspected image and the reference image are processed so that the weight 1 (100%) is set from the contour line 10 to the outside valid distance m and the weight becomes zero with the primary proportion at a distance n from the contour line extending further outward beyond the outside valid distance m. Likewise, the inspected image and the reference image are processed so that the weight 1 (100%) is set from the contour line 10 to the inside valid distance m and the weight becomes zero with the primary proportion at a distance n from the contour line extending further inward beyond the inside valid distance m. In this case, the following operation is executed.

In the reference image data processing step (S142), the image processing unit 78 generates the reference image (b) by executing filter processing (data processing) on all data of the target reference image (a), using a filter function in which the weight 1 (100%) is set from the contour line 10 to the valid distance m and the weight becomes zero at the distance n in the normal direction from the position of the contour line with the primary proportion from the valid distance m, for each reference image (a) (image before data processing). Data of the processed reference image (b) is stored in the storage device 80 and is output to a comparison circuit 108.

In the inspected image data processing step (S144), the image processing unit 77 generates the inspected image (b) by executing filter processing (data processing) on all data of the target inspected image (a), using a filter function in which the weight 1 (100%) is set from the contour line 10 to the valid distance m and the weight becomes zero at the distance n in the normal direction from the position of the contour line with the primary proportion from the valid distance m, for each inspected image (a) (image before data processing). Data of the processed inspected image (b) is stored in the storage device 79 and is output to the comparison circuit 108.

Here, the valid distance m is preferably set to a distance A from the edge (contour line) of the figure pattern described in FIG. 13 to the 20% level, for example, and a distance B from the edge (contour line) of the figure pattern to the 80% level, for example. In addition, the distance n is preferably set to a distance of 1 to 3 pixels (for example, 2 pixels) from the valid distance m.

The other steps are the same as those in the second embodiment.

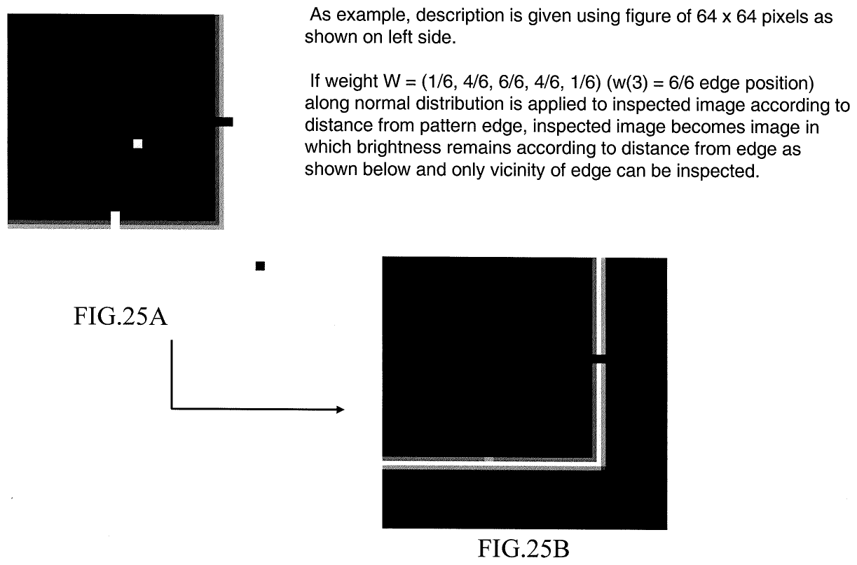

FIGS. 25A and 25B are diagrams showing an example of an inspected image in the third embodiment. For an inspected image (a) of 64×64 pixels shown in FIG. 25A, data processing is performed with weighting along the normal distribution as shown in FIG. 23, according to the distance from the contour line 10 of the figure pattern. As a result, as shown in FIG. 25B, the inspected image becomes an image in which a brightness in the vicinity of the edge of the figure pattern remains and only the vicinity of the edge of the figure pattern can be inspected.

As described above, according to the third embodiment, it is possible to detect large defects in the vicinity of the outer circumferential line 12 and in the vicinity of the inner circumferential line 14 while reducing pseudo defects at positions deviated from the valid inspection regions 1 and 2.

### Fourth Embodiment

In a fourth embodiment, a configuration in which a filter function according to the third embodiment is further improved will be described. A configuration of an inspection apparatus 100 in the fourth embodiment is the same as that of FIG. 15. Further, a flowchart showing main steps of an inspection method in the fourth embodiment is the same as that in FIG. 16 for a die to database inspection. A die to die inspection is the same as that in FIG. 19. Contents other than points specifically described below are the same as those in the second embodiment.

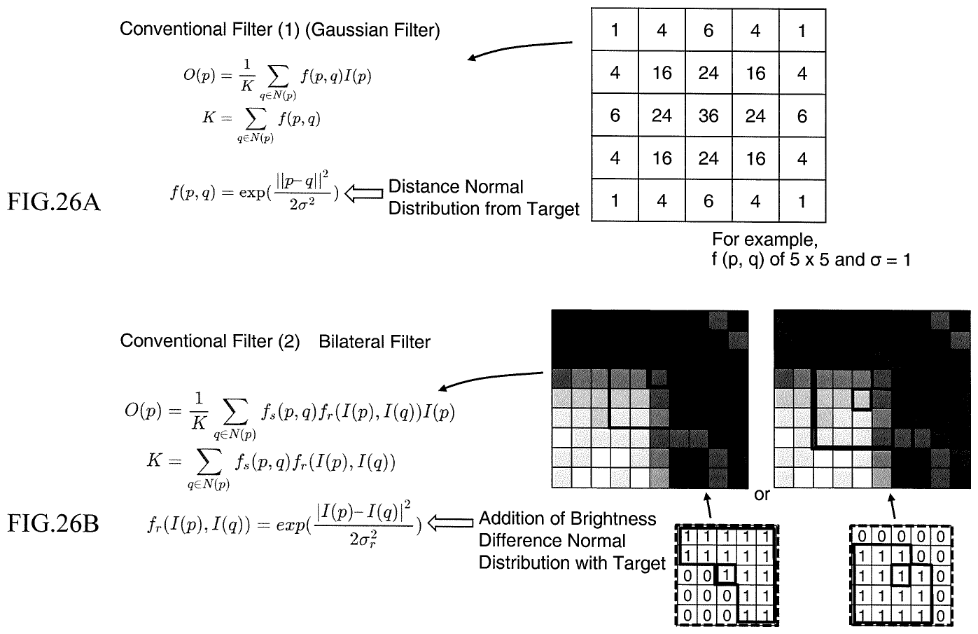

FIGS. 26A and 26B are diagrams showing an example of a filter function in a first comparative example of the fourth embodiment. FIG. 26A shows an example of a Gaussian filter that performs filter processing on all pixels of an image to perform weighting with a normal distribution according to a distance from a target with no relation to a contour line. FIG. 26B shows an example of a bilateral filter (bilateral filter function) that combines a normal distribution filter kernel (normal distribution filter function) fs(p,q) performing weighting with a normal distribution according to a distance from a target with no relation to a contour line and a brightness difference filter kernel (brightness difference filter function) fr(I(p),I(q)) performing weighting regarding a pixel having a close brightness around a target pixel as a closely related pattern element, the bilateral filter performing weighting and performs filter processing on all pixels of an image. Even if data of the inspected image and the reference image are processed using each filter in the comparative example shown in FIGS. 26A and 26B, a constant effect on noise reduction is recognized, but a defect of a region sufficiently separated from an edge of a figure pattern may be detected as in the related art. For this reason, it is not possible to sufficiently reduce pseudo defects. Therefore, in the fourth embodiment, a filter for performing weighting according to the distance from the contour line of the figure pattern is further combined.

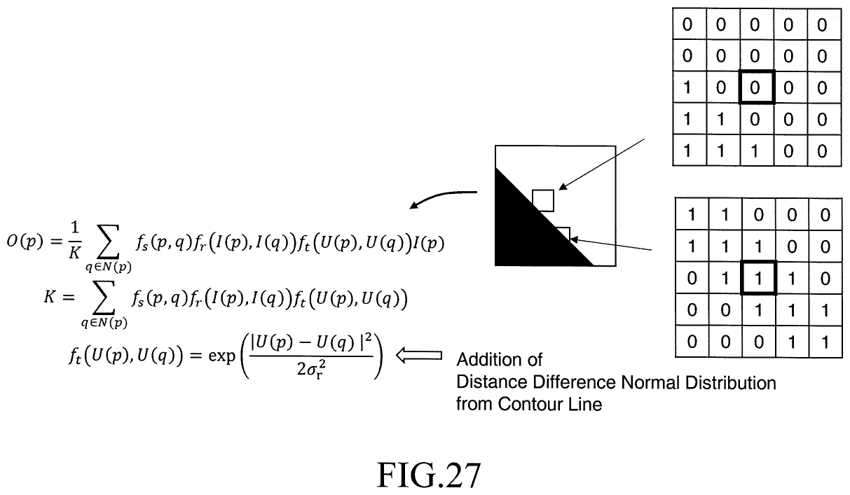

FIG. 27 is a diagram showing an example of a contour line distance combination filter function in the fourth embodiment. In the example of FIG. 27, a combination filter obtained by combining the bilateral filter shown in FIG. 26B with a contour line distance filter kernel (contour line distance filter) ft(U(p),U(q)) performing weighting according to the distance from the contour line is shown. A normal distribution filter kernel fs(p,q) of the bilateral filter can be defined by a 5×5 coefficient matrix of a normal distribution using weight components 1, 4, 6, 16, 24, and 36 with no relation to a brightness (gray value), as shown in FIG. 26A. Further, a brightness difference filter kernel fr(I(p),I(q)) can be defined by a 5×5 coefficient matrix using weight components 0 and 1 in which a peripheral pixel having a brightness close to a brightness (gray value) of a target pixel is defined as 1 and a peripheral pixel having a brightness far from the brightness of the target pixel is defined as 0, as shown in FIG. 26B. Further, a contour line distance filter kernel ft(U(p), U(q)) can be defined by a 5×5 coefficient matrix using weight components 0 and 1 in which pixels overlapping with the contour line are defined as 1 and the other pixels are defined as 0, as shown in FIG. 27.

Further, a gray value (pixel value) O(p) after filter processing of each pixel by the contour line distance combination filter is defined by a value obtained by dividing a sum of products of a pixel I(p) of k×k pixels (for example, 5×5 pixels) around a target pixel and coefficient matrixes (p,q)·fr(I(p), I(q))·ft′(U(p),U(q)) by a sum K of coefficient matrixes fs(p,q)·fr(I(p), I(q))·ft(U(p),U(q)), as shown in FIG. 27.

In the example of FIG. 27, in the contour line distance filter kernel ft(U(p), U(q)), the pixels overlapping with the contour line are defined as 1 and the other pixels are defined as 0. However, the present disclosure is not limited thereto. In the fourth embodiment, for improvement, it is preferable to change the weight according to the distance from the contour line as the contour line distance filter kernel ft(U(p),U(q)). For example, as described later, a weight component 6/6 is set to the pixels on the contour line and a weight component decreases to 4/6, 2/6, 1/6, and 0 as the distance from the contour line increases.

In a data processing step (S140), an image processing circuit 134 (image processing unit) processes an inspected image (a) and a reference image (a), using the contour line distance combination filter function obtained by combining the contour line distance filter kernel ft(U(p),U(q)) weighting data of the inspected image (a) and data of the reference image (a) according to a distance from the contour line 10 with the kernel of the bilateral filter.

In a reference image data processing step (S142), an image processing unit 78 generates a reference image (b) by executing filter processing (data processing) on all data of the target reference image (a), using the contour line distance combination filter function in which the contour line distance filter kernel ft(U(p),U(q)) performing weighting according to a distance from the contour line 10 is combined, for each reference image (a) (image before data processing). Data of the processed reference image (b) is stored in the storage device 80 and is output to a comparison circuit 108.

In an inspected image data processing step (S144), an image processing unit 77 generates an inspected image (b) by executing filter processing (data processing) on all data of the target inspected image (a), using the contour line distance combination filter function in which the contour line distance filter kernel ft(U(p),U(q)) performing weighting according to a distance from the contour line 10 is combined, for each inspected image (a) (image before data processing). Data of the processed inspected image (b) is stored in the storage device 79 and is output to the comparison circuit 108.

The other steps are the same as those in the second embodiment.

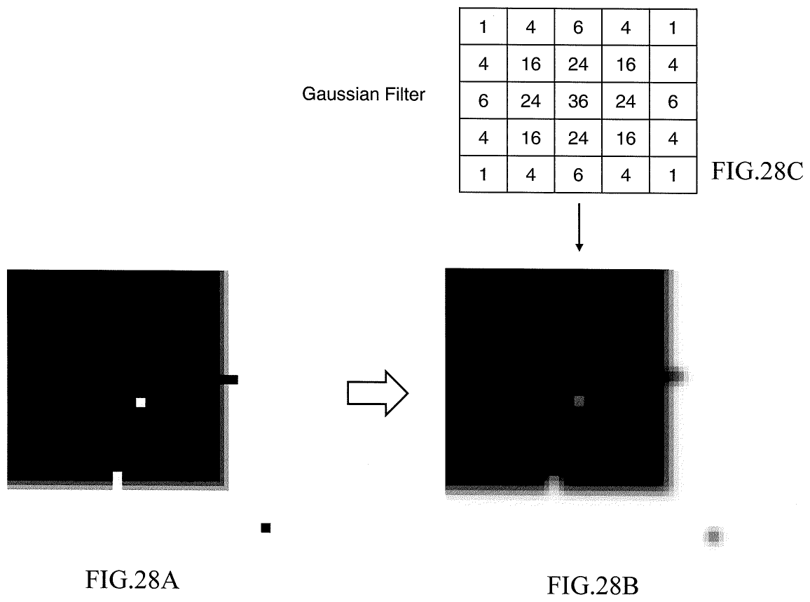

FIGS. 28A to 28C are diagrams showing an example of an inspected image filtered by a Gaussian filter in the first comparative example of the fourth embodiment. In the example of FIG. 28B, a result obtained by convolving a normal distribution filter kernel fs(p,q) of a 5×5 coefficient matrix using weights 1, 4, 16, 24, and 36 shown in FIG. 28C on the inspected image shown in FIG. 28A is shown. By performing averaging with a normal distribution, the image is blurred as shown in FIG. 28B.

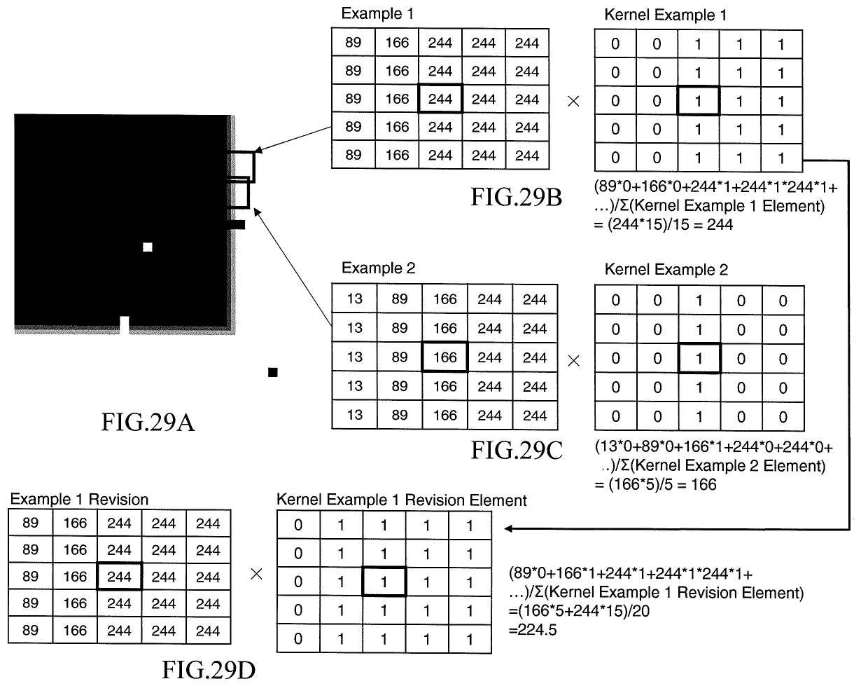

FIGS. 29A to 29D are diagrams showing an example of an inspected image filtered by a brightness difference filter in a second comparative example of the fourth embodiment. In the examples of FIGS. 29B and 29C, for example, as a brightness difference filter kernel fr(I(p),I(q)), a 5×5 coefficient matrix using weight components 0 and 1 in which pixels are defined as 1 in the case where a target pixel and a peripheral pixel are close, for example, a brightness difference is equal to or less than ±10% and are defined as 0 in the other cases is used. If filter processing is performed by a brightness difference filter based on the brightness difference filter kernel fr(I(p),I(q)) shown in the examples of FIGS. 29B and 29C, in the case of a simple inspected image shown in FIG. 28A, even though convolution calculation by the kernel is performed, the brightness becomes the same as the original brightness, as shown in FIG. 29A. On the other hand, if the brightness difference filter kernel fr(I(p),I(q)) (kernel 2) shown in FIG. 29B is set as a 5×5 coefficient matrix using weight components 0 and 1 in which pixels are defined as 1 in the case where a brightness difference is equal to or less than ±50% and are defined as 0 in the other cases, shown in FIG. 29D, the brightness after filter calculation changes.

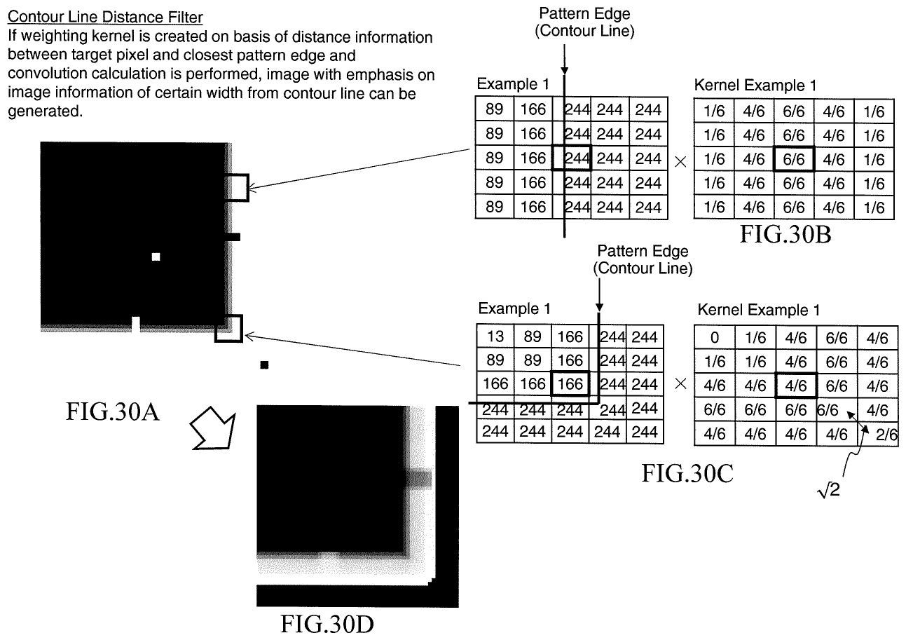

FIGS. 30A to 30D are diagrams showing an example of an inspected image filtered by a contour line distance independent filter in a third comparative example of the fourth embodiment. In the examples of FIGS. 30B and 30C, for example, as the contour line distance filter kernel ft(U(p),U(q)), a 5×5 coefficient matrix in which a weight component 6/6 is set to the pixels on the contour line and a weight component decreases to 4/6, 2/6, and 1/6 as the distance from the contour line increases is used. An inspected image of a result obtained by convolving the contour line distance filter kernel ft(U(p),U(q)) shown in FIG. 30B or 30C on the inspected image shown in FIG. 30A is shown in FIG. 30D. If a weighting kernel is created on the basis of distance information between a target pixel and a closest pattern edge and convolution calculation is performed, as shown in FIG. 30D, an image with emphasis on image information of a certain width from the pattern edge can be generated. Since the third comparative example merely changes the weight according to the distance from the contour line, the third comparative example is substantially the same as the third embodiment. Therefore, the inspected image becomes an image in which a brightness in the vicinity of the edge of the figure pattern remains and only the vicinity of the edge of the figure pattern can be inspected.

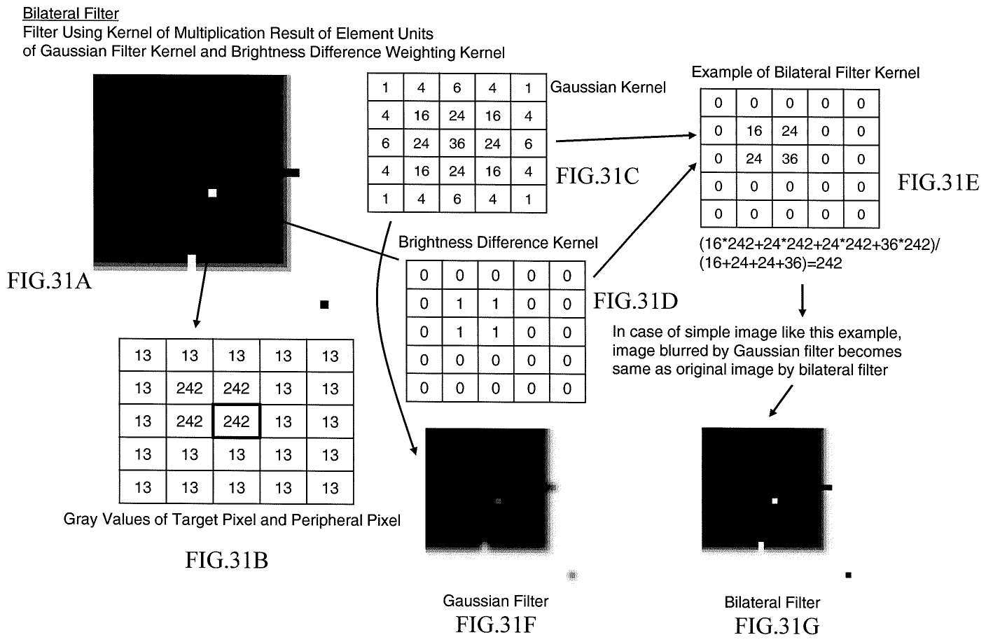

FIGS. 31A to 31G are diagrams showing an example of an inspected image filtered by a bilateral filter in a fourth comparative example of the fourth embodiment. In the example of FIG. 31C, as the normal distribution filter kernel fs(p,q) (Gaussian filter kernel), for example, a 5×5 coefficient matrix using weight components 1, 4, 16, 24, and 36 is used. Further, in the example of FIG. 31D, as the brightness difference filter kernel fr(I(p),I(q)), a 5×5 coefficient matrix using weight components 0 and 1 in which pixels are defined as 1 in the case where a target pixel and a peripheral pixel are close, for example, a brightness difference is equal to or less than −10% and are defined as 0 in the other cases is used. As the bilateral filter kernel (bilateral filter function) obtained by multiplying these kernels, as shown in FIG. 31E, a 5×5 coefficient matrix using weight components 0, 16, 24, and 36 is used. If the normal distribution filter kernel fs(p,q) shown in FIG. 31C is convolved on the inspected image shown in FIG. 31A, having pixel values shown in FIG. 31B, as shown in FIG. 31F, a blurred image is obtained. On the other hand, if the bilateral filter kernel shown in FIG. 31E is convolved on the inspected image shown in FIG. 31A, having the pixel values shown in FIG. 31B, the image blurred by the normal distribution filter becomes the same as the original image by the bilateral filter, as shown in FIG. 31G.

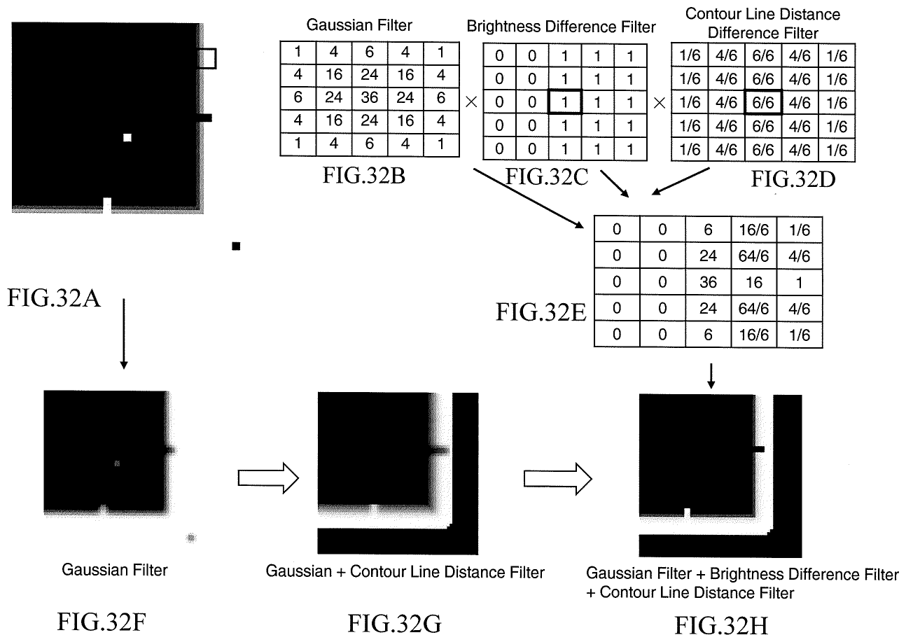

FIGS. 32A to 32H are diagrams showing an example of an inspected image filtered by a contour line distance combination filter in the fourth embodiment. In the example of FIG. 32B, as the normal distribution filter kernel fs(p,q) (Gaussian filter kernel), for example, a 5×5 coefficient matrix using weight components 1, 4, 16, 24, and 36 is used. Further, in the example of FIG. 32C, as the brightness difference filter kernel fr(I(p),I(q)), a 5×5 coefficient matrix using weight components 0 and 1 in which pixels are defined as 1 in the case where a target pixel and a peripheral pixel are close, for example, a brightness difference is equal to or less than ±10% and are defined as 0 in the other cases is used. Further, in the example of FIGS. 32D, as the contour line distance filter kernel ft(U(p),U(q)), for example, a 5×5 coefficient matrix in which a weight component 6/6 is set to the pixels on the contour line and a weight component decreases to 4/6 and 1/6 as the distance from the contour line increases is used. As the contour line distance combination filter kernel obtained by multiplying these kernels, as shown in FIG. 32E, for example, a 5×5 coefficient matrix using weight components 0, 1, 6, 16, 24, 36, 1/6, 4/6, 16/6, and 64/6 is used. If the normal distribution filter kernel fs(p,q) shown in FIG. 32B is convolved on the inspected image shown in FIG. 32A, as shown in FIG. 32F, a blurred image is obtained. On the other hand, as shown in FIG. 32G, if the product of the normal distribution filter kernel fs(p,q) and the contour line distance filter kernel ft(U(p),U(q)) is convolved on the inspected image shown in FIG. 32A, an image with emphasis on image information of a certain width from a pattern edge while being blurred by the normal distribution filter can be generated. Further, if the contour line distance combination filter kernel in the fourth embodiment shown in FIG. 32E is convolved on the inspected image shown in FIG. 32A, as shown in FIG. 32H, an image with emphasis on image information of a certain width from a pattern edge where the brightness difference is clear can be generated.

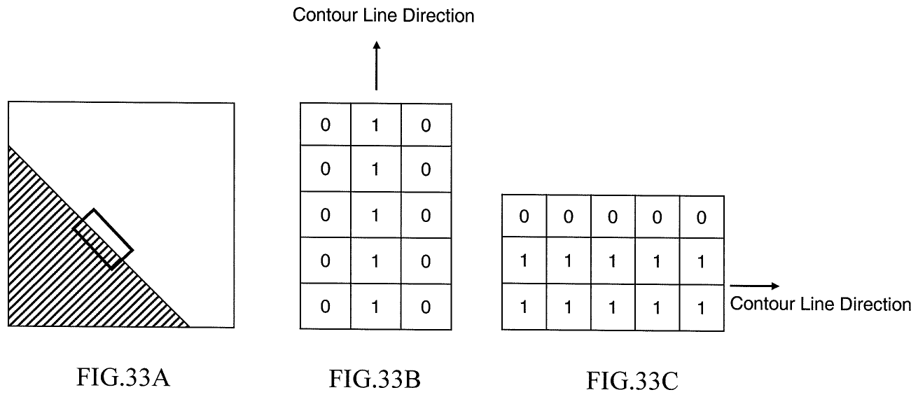

FIGS. 33A to 33C are diagrams showing an example of a contour line distance filter kernel in a modification of the fourth embodiment. A contour line direction is not matched with a pixel division direction (x,y direction), as shown in FIG. 33A. Therefore, as shown in FIG. 33B or 33C, a 5×3 coefficient matrix in which the contour line distance filter kernel ft(U(p),U(q)) becomes parallel to the contour line direction is used. By rotating a pixel setting direction, for example, a 5×3 coefficient matrix of 5 rows in the contour line direction and 3 columns in a normal direction of the contour line is used. As a result, weighting corresponding to two pixels from the contour line is enabled. Since the number of columns can be reduced by following the contour line direction, the number of calculations can be reduced. In FIGS. 33B and 33C, in the contour line distance filter kernel ft(U(p),U(q)), the pixels overlapping with the contour line are defined as 1 and the other pixels are defined as 0. However, the present disclosure is not limited thereto. In the modification of the fourth embodiment, although not shown in the drawings, the weight may be changed according to the distance from the contour line as the contour line distance filter kernel ft(U(p),U(q)). For example, the weight component of the center row is set to 6/6 and the weight components of the rows on both sides are set to 1/6. It goes without saying that the weight component becomes 0 if the distance from the contour line further increases.

As described above, according to the fourth embodiment, it is possible to detect large defects in the vicinity of an outer circumferential line 12 and in the vicinity of an inner circumferential line 14 while reducing pseudo defects at positions deviated from valid inspection regions 1 and 2 and it is possible to reduce noise of an image in the valid inspection regions 1 and 2.

In the above description, a series of “circuits” includes a processing circuit and an electric circuit, a computer, a processor, a circuit board, a quantum circuit, or a semiconductor device is included in the processing circuit. Further, a common processing circuit (same processing circuit) may be used for each “circuit”. Alternatively, a different processing circuit (separate processing circuit) may be used. A program for executing a processor or the like may be recorded on a record carrier body such as a magnetic disk drive, a magnetic tape device, an FD, or a read only memory (ROM). For example, the position circuit 107, the comparison circuit 108, the reference image generation circuit 112, the contour data generation circuit 130, the defect selection circuit 132, and the image processing circuit 134 may be configured by at least one processing circuit described above.

The embodiments have been described with reference to the specific examples. However, the present disclosure is not limited to these specific examples.

Further, descriptions of parts and the like that are not directly necessary for explanation of the present disclosure, such as the apparatus configuration and the control method, are omitted. However, the necessary apparatus configuration and control method can be appropriately selected and used.

Further, all pattern inspection apparatuses and pattern inspection methods including the elements of the present disclosure and capable of being appropriately designed and changed by those skilled in the art are included in the scope of the present disclosure.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern inspection apparatus comprising:
an inspected image acquisition mechanism configured to acquire an inspected image of a figure pattern formed on an inspection target object, using an electron beam;
a reference image generation processing circuit configured to generate a reference image corresponding to the inspected image;
a contour data generation processing circuit configured to generate contour data defining a contour line of the figure pattern;
a comparison processing circuit configured to compare the inspected image and the reference image and determine whether there is a defect based on a result of a comparison; and
a defect selection processing circuit configured to select a defect within a range preset based on the contour line as a valid defect, from at least one defect determined to be a defect by the comparison, using the contour data.

2. The apparatus according to claim 1, further comprising:
a distance calculation processing circuit configured to calculate a distance from each defect position of the at least one defect to the contour line.

3. The apparatus according to claim 2, further comprising:
a search processing circuit configured to search for a contour line close to each defect position of the at least one defect, wherein the distance calculation processing circuit calculates a distance from the each defect position to a corresponding contour line searched.

4. A pattern inspection apparatus comprising:
an inspected image acquisition mechanism configured to acquire an inspected image of a figure pattern formed on an inspection target object, using an electron beam;
a reference image generation processing circuit configured to generate a reference image corresponding to the inspected image;
a contour data generation processing circuit configured to generate contour data defining a contour line of the figure pattern;
an image processing circuit configured to process the inspected image and the reference image using the contour data; and
a comparison processing circuit configured to compare the inspected image processed and the reference image processed.

5. The apparatus according to claim 4, wherein the image processing circuit processes the inspected image and the reference image to exclude a region outside a range preset based on the contour line from an inspection region.

6. The apparatus according to claim 4, wherein the image processing circuit weights data of the inspected image and data of the reference image, according to a distance from the contour line.

7. The apparatus according to claim 5, wherein the image processing circuit excludes a region outside a range preset inside the contour line based on the contour line from the inspection region.

8. The apparatus according to claim 7, wherein the image processing circuit excludes a region outside a range preset outside the contour line on the basis of the contour line from the inspection region.

9. The apparatus according to claim 4, wherein the image processing circuit processes the inspected image and the reference image, using a combination filter obtained by combining a bilateral filter function, which combines a normal distribution filter function performing weighting with a normal distribution according to a distance from a target pixel with no relation to the contour line and a brightness difference filter function performing weighting regarding a pixel having a close brightness around the target pixel as a closely related pattern element, the bilateral filter function performing filter processing on all pixels of the inspected image and the reference image, with a contour line distance filter function performing weighting according to a distance of the target pixel from the contour line.

10. A pattern inspection method comprising:
acquiring an inspected image of a figure pattern formed on an inspection target object, using an electron beam;
generating a reference image corresponding to the inspected image;
generating contour data defining a contour line of the figure pattern;
comparing the inspected image and the reference image and determining whether there is a defect based on a result of a comparison; and
selecting a defect within a range preset based on the contour line as a valid defect, from at least one defect determined to be a defect by the comparison, using the contour data, and outputting the defect.

11. A pattern inspection apparatus comprising:
an inspected image acquisition mechanism configured to acquire an inspected image of a figure pattern formed on an inspection target object, using an electron beam;
a contour data generation processing circuit configured to generate contour data defining a contour line of the figure pattern;
a comparison processing circuit configured to compare first and second inspected images provided with the same pattern and determine whether there is a defect based on a result of a comparison; and
a defect selection processing circuit configured to select a defect within a range preset based on the contour line as a valid defect, from at least one defect determined to be a defect by the comparison, using the contour data.

12. A pattern inspection apparatus comprising:
an inspected image acquisition mechanism configured to acquire an inspected image of a figure pattern formed on an inspection target object, using an electron beam;
a contour data generation processing circuit configured to generate contour data defining a contour line of the figure pattern;
an image processing circuit configured to process first and second inspected images provided with the same pattern using the contour data; and
a comparison processing circuit configured to compare the first and second inspected images processed.
